(19) United States
(12) Patent Application Publication
(10) Pub. No.: US 2010/0026331 A1
(43) Pub. Date: Feb. 4, 2010

(54) Construction Structures and Manufacturing Processes for Integrated Circuit Wafer Probe Card Assemblies

(76) Inventors: Fu Chiung Chong, Saratoga, CA (US); W.R. Bottoms, Palo Alto, CA (US); Erh-Kong Chieh, Cupertino, CA (US); Anna Litza, Cupertino, CA (US); Douglas L. McKay, San Jose, CA (US); Roman L. Milter, San Francisco, CA (US); Sha Li, San Jose, CA (US)

Correspondence Address: GLENN PATENT GROUP, 3475 EDISON WAY, SUITE L, MENLO PARK, CA, 94025, US

(21) Appl. No.: 12/517,528

(22) PCT Filed: Dec. 4, 2007
(86) PCT No.: PCT/US07/86394

§ 371 Date: Jun. 3, 2009

Related U.S. Application Data
(60) Provisional application No. 60/898,964, filed on Jan. 31, 2007.
(60) Provisional application No. 60/891,192, filed on Feb. 22, 2007.
(60) Provisional application No. 60/868,535, filed on Dec. 4, 2006.

(51) Int. Cl. G01R 31/02

(52) U.S. Cl. 324/757

(57) ABSTRACT

Enhanced microfabricated spring contact structures and associated methods, e.g. such as for electrical contactors and interposers, comprise improvements to spring structures that extend from the substrate surface, and/or improvements to structures on or within the support substrate. Improved spring structures and processes comprise embodiments having selectively formed and etched, coated and/or plated regions, which are optionally further processed through planarization and/or annealment. Enhanced solder connections and associated processes provide a gap between substrates for componentry, and or improved manufacturing techniques using distributed spacers. Enhanced probe card assembly structures and processes provide improved planarization adjustment and thermal stability.

### CROSS REFERENCE TO RELATED APPLICATIONS

This Application is a National Phase entry of PCT/US2007/86394 filed 4 Dec. 2007, which claims priority to U.S. Provisional Application No. 60/868,535, entitled Construction Structures and Manufacturing Processes for Integrated Circuit Wafer Probe Card Assemblies, filed 4 Dec. 2006, to U.S. Provisional Application No. 60/898,964, entitled Structures and Processes for Fabrication of Probe Card Assemblies with Multi-Layer Interconnect, filed 31 Jan. 2007, and to U.S. Provisional Application No. 60/891,192, entitled Fine Pitch Probe Card Having Rapid Fabrication Cycle, filed 22 Feb. 2007.

Each of the aforementioned documents is incorporated herein in its entirety by this reference thereto.

### FIELD OF THE INVENTION

The present invention relates generally to the field of miniaturized spring contacts and spring probes for high density electrical interconnection systems. More particularly, the present invention relates to microfabricated spring contact methods and apparatus and associated assembly structures and processes, and improvements thereto, for making electrical connections to semiconductor integrated circuits (ICs) having increasingly higher density and finer pitch input/output connections and the next level of interconnect in applications including but not limited to semiconductor device testing and packaging.

### BACKGROUND OF THE INVENTION

Advances in semiconductor integrated circuit design, processing, and packaging technologies have resulted in increases in the number and density of input/output (I/O) connections on each die and as well as in an increase in the diameter of the silicon wafers used in device fabrication. With increasing numbers of I/O connections per die, the cost of testing each die becomes a greater and greater fraction of the total device cost. The test cost fraction can be reduced by either reducing the time required to test each die or by testing multiple die simultaneously.

Probe cards may be used to test single or multiple die simultaneously at the wafer level prior to singulation and packaging. In multiple die testing applications, the requirements for parallelism between the array of spring probe tips on the probe card and the semiconductor wafer become increasingly stringent since the entire array of spring probe tips are required to make simultaneous electrical contact over large areas of the wafer.

With each new generation of IC technology, the I/O pitch tends to decrease and the I/O density tends to increase. These trends place increasingly stringent requirements on the probe tips and associated probe card structures. Fine pitch probe tips are required to be smaller in width and length while continuing to generate the force required to achieve and maintain good electrical connections with the device under test. The force required to achieve a good electrical connection is a function of the processing history of the IC contact pad, such as but not limited to the manner of deposition, the temperature exposure profile, the metal composition, shape, surface topology, and the finish of the spring probe tip. The required force is also typically a function of the manner in which the probe tip “scrubs” the surface of the contact pad.

As the probe pitch decreases, the linear dimensions of the IC connection terminal contact areas also decreases leaving less room available for the probe tips to scrub. Additionally, the probes must be constructed to avoid damaging the passivation layer that is sometimes added to protect the underlying IC devices (typically 5-10 microns in thickness). Additionally, as the spring probe density increases, the width and length of the probes tends to decrease and the stress within the probe tends to increase, to generate the force required to make good electrical contact to the IC connection terminal contact areas.

There is a need for probe cards for fine pitch probing comprised of an array of spring probe contacts capable of making simultaneous good electrical connections to multiple devices on a semiconductor wafer under test in commercially available wafer probers using specified overdrive conditions over large areas of a semiconductor wafer and or over an entire wafer. To accomplish this, the array of spring probe contacts on the probe card should be co-planar and parallel to the surface of the semiconductor wafer to within specified tolerances such that using specified overdrive conditions, the first and last probes to touch the wafer will all be in good electrical contact with the IC device yet not be subject to over stressed conditions which could lead to premature failure. Additionally, any changes in the Z position, e.g. due to set or plastic deformation, or condition of the probe tips, e.g. diameter, surface roughness, etc., over the spring probe cycle life should remain within specified acceptable limits when operated within specified conditions of use, such as but not limited to overdrive, temperature range, and/or cleaning procedures.

Micro-fabricated spring contacts are potentially capable of overcoming many of the limitations associated with conventionally fabricated spring contacts, e.g. tungsten needle probes, particularly in fine pitch probing applications over large substrate areas. Micro-fabricated spring contacts can be fabricated using a variety of photolithography based techniques known to those skilled in the art, e.g. Micro-Electro-Mechanical Systems (MEMS) fabrication processes and hybrid processes such as using wire bonds to create spring contact skeletons and MEMs or electroplating processes to form the complete spring contact structure. Arrays of spring contacts can be either be mounted on a contactor substrate by pre-fabricating and transferring them (either sequentially or in mass parallel) to the contactor substrate or by assembling each element of the spring contact array directly on the contactor substrate, such as by using a wire bonder along with subsequent batch mode processes.

Micro-fabricated spring contacts may be fabricated with variety of processes known to those skilled in the art. Exemplary monolithic micro-fabricated spring contacts may comprise stress metal springs having one or more layers of built-in or initial stress that are photolithographically patterned and fabricated on a substrate using batch mode semiconductor manufacturing processes. As a result, the spring contacts are fabricated en masse, and can be fabricated with spacings equal to or less than that of fine pitch semiconductor device electrical connection terminals or with spacings equal to or greater than those of printed circuit boards, i.e. functioning as an electrical signal space transformer.

In exemplary stress metal spring contacts, an internal stress gradient created within the spring contact causes a free portion of the spring contact to bend up and away from the substrate to a lift height that is determined by the magnitude of the stress gradient. An anchor portion remains fixed to the substrate and is electrically connected to a first contact pad on the substrate. The spring contact is made of an elastic material, which provides the free portion of the spring contact with flexibility and mechanical compliance. The force generated by stress metal spring contacts can be increased by the application of one or more plated metal layers comprising metals and metal alloys with appropriate Young's modulii, such as nickel or nickel cobalt, etc. Increasing the spring force helps to establish reliable electrical contacts and can also help to compensate for mechanical variations and induced by temperature changes and other environmental factors.

Photolithographically patterned spring structures are particularly useful in electrical contactor applications where it is desired to provide high density electrical contacts which may extend over relatively large contact areas and which also may exhibit relatively high mechanical compliance in the normal direction relative to the plane of the contact area. Such electrical contactors are useful for applications including integrated circuit device testing (both in wafer and packaged formats), integrated circuit packaging (including singulated device packages, wafer scale packaging, and multiple chip packages) and electrical connectors (including board level, module level, and device level, e.g. sockets. Photolithographically patterned spring structures are also well suited for the fabrication of electrical interposers capable of providing compliant electrical connections between arrays of electrical contacts.

Interposers, having many contacts in parallel, can be subject to contamination from particulates or other contamination layers, e.g. surface contamination layers, which may cause unreliable electrical contact under use conditions, such as including repeated mechanical and thermal cycling. A controlled increase of interposer contact force is associated with an increase in the reliability of the electrical contacts under use conditions, as well as during aging and storage in environments in which surface contamination films can form. While it is desirable to increase the contact force, it is undesirable to increase contact force excessively, since the force to compress the interposer becomes too high, which may cause unacceptable mechanical deflection of the interposer and probe card structures.

It may therefore be desirable to provide interposers designed to have sufficient contact force to provide high quality low resistance electrical connections yet not so high that excessive forces are generated on adjacent structures.

Lift height non-uniformity can be caused by numerous factors including but not limited to variations in the internal stress gradient of stress metal springs, variations in the substrate thickness, and variations in lift height associated with plating processes, variations in lift height due to thermal processes, and variations in lift height due to assembly fabrication processes.

As device pitch decreases and for other reasons mentioned above, it would be desirable for micro fabricated contactors and interposers to possess contact elements having increasing higher levels planarization and/or lift height uniformity.

It would be advantageous to provide a method and structure to fabricate improved microfabricated spring contacts either directly or indirectly across the surface of substrate areas, which can provide increased strength, longevity, and planarity, as well as superior electrical contact performance, over a wide variety of operating conditions e.g. temperature, cycle life, overdrive, pad metal, etc. Such a development would provide a significant technical advance.

Furthermore, it would be advantageous to provide cost-effective assembly structures and methods for thermal processing of microcontactor assemblies. Such improvements would provide an additional technical advance.

As well, it would be advantageous to provide enhanced probe card structures and associated processes, such as to improve setup, servicing, and thermal performance. Such improvements would provide a major technical advance.

### SUMMARY OF THE INVENTION

Enhanced microfabricated spring contact structures and associated methods, e.g. such as for electrical contactors and interposers, comprise improvements to spring structures that extend from the substrate surface, and/or improvements to structures on or within the support substrate. Improved spring structures and processes comprise embodiments having selectively formed and etched, coated and/or plated regions, which are optionally further processed through planarization and/or annealment. Enhanced solder connections and associated processes provide a gap between substrates for componentry, and or improved manufacturing techniques using distributed spacers. Enhanced probe card assembly structures and processes provide improved planarization adjustment and thermal stability.

### BRIEF DESCRIPTION OF THE DRAWINGS

FIG. 1 is a schematic view of an exemplary probe card assembly for testing single die on a silicon wafer;

FIG. 2 is a schematic side view of an exemplary contactor assembly comprising an array of compliant micro-fabricated spring contacts;

FIG. 3 is a detailed partial cross sectional view of an interposer structure;

FIG. 4 is a partial schematic cutaway view of enhanced solder connection structures between planar components;

FIG. 5 is a partial schematic view of a probe chip to Z-Block Assembly Fixture, such as using shim dots and/or spheres;

FIG. 6 is a partial schematic cutaway view of a planarization fixture with a flat reference plate and using shim dots and/or spheres;

FIG. 7 is a schematic plan view of a planarization fixture with a flat reference plate and using shim dots and/or spheres;

FIG. 8 is a partial schematic cutaway view of a planarization fixture with fabricated precision wells defined in a flat reference plate;

FIG. 9 is a schematic plan view of a planarization fixture with fabricated precision wells defined in a flat reference plate;

FIG. 10 is a schematic view of an exemplary planarization fixture;

FIG. 11 shows a soldered probe chip probe card embodiment having a double-sided upper interposer;

FIG. 12 shows a soldered probe chip probe card embodiment having a single sided upper interposer;

FIG. 13 is an upward plan view of an LCD platform structure;

FIG. 14 is a side view of an LCD platform structure;

FIG. 15 is a cross sectional side view of an LCD platform structure;

FIG. 16 is an expanded assembly view of push-pull activator for an LCD platform structure;

FIG. 17 is a detailed cutaway view of push-pull activator for an LCD platform structure;

FIG. 18 is a schematic view of a probe chip contactor interface assembly, comprising a daughter card attached to a probe chip contactor assembly, and further comprising stiffening means;

FIG. 19 is an expanded assembly view of a probe assembly having a thermal stiffener structure;

FIG. 20 is a partial cutaway view of a probe assembly having a thermal stiffener structure;

FIG. 21 is a partial cutaway view of an alternate probe assembly having a thermal stiffener structure;

FIG. 22 is a cross sectional view of an interposer plating fixture;

FIG. 23 is an expanded assembly view of an exemplary interposer plating fixture;

FIG. 24 shows an exemplary interposer plating process;

FIG. 25 is an expanded process flow diagram for an interposer plating process;

FIG. 26 shows a partial cutaway view of an interposer structural element after photolithography and before lifting;

FIG. 27 shows a partial cutaway view of an interposer structural element after lifting of spring elements;

FIG. 28 shows a partial cutaway view of an interposer structural element after plating of lifted spring elements;

FIG. 29 shows a partial plan view of an interposer structural element after plating of lifted spring elements;

FIG. 30 shows a detailed partial plan view of an interposer structural element after plating of lifted spring elements;

FIG. 31 shows a soldered probe chip probe card embodiment having a double-sided upper interposer;

FIG. 32 shows a soldered probe chip probe card embodiment having a single sided upper interposer; and

FIG. 33 is a partial cutaway view of an exemplary embodiment of multi-layer routing on the front and back side of a probe chip.

### DETAILED DESCRIPTION OF PREFERRED EMBODIMENTS

Micro-fabricated spring contacts may be fabricated with a variety of processes known to those skilled in the art. Exemplary monolithic micro-fabricated spring contacts may comprise stress metal springs that are photolithographically patterned and fabricated on a substrate using batch mode semiconductor manufacturing processes. As a result, the spring contacts are fabricated en masse, and can be fabricated with spacings equal to or less than that of semiconductor bonding pads or with spacings equal to or greater than those of printed circuit boards, i.e. functioning as an electrical signal space transformer.

Fabrication of high density arrays of spring contacts are also possible using monolithic micro-fabrication processes wherein arrays of elastic, i.e. resilient, core members, i.e. spring contact skeleton structures, are fabricated directly on a contactor substrate utilizing thick or thin film photolithographic batch mode processing techniques such as those commonly used to fabricate semiconductor integrated circuits.

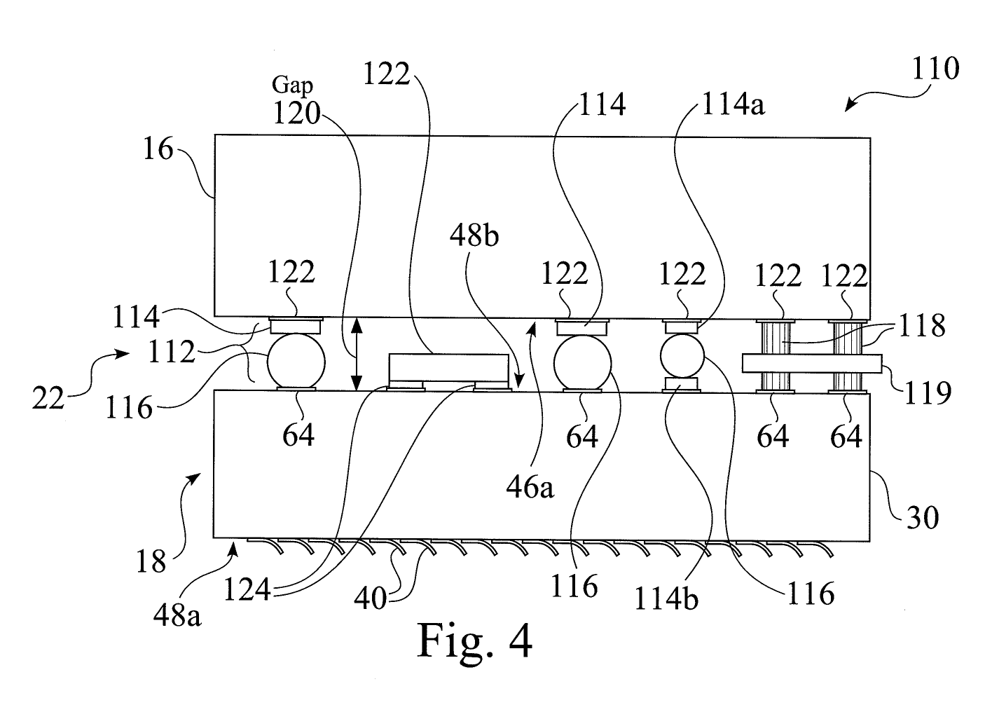

The spring constant of the spring is a function of the Young's modulus of the material used to fabricate the spring and the length, width, and thickness of the spring. The spring constant of the spring can be increased by enveloping the springs 40 with a coating of a metal including but not limited to electroplated, or sputtered, or CVD deposited nickel or a nickel alloy, gold, or a palladium alloy such as palladium cobalt (see FIG. 4).

The spring constant can be varied over many orders of magnitude by controlling the thickness of the deposited coating layer, the geometrical characteristics of the spring, and the choice of metal and the thickness and number of coatings. Making the springs thicker both increases the contact force and the robustness of the physical and electrical contact between the spring and its contact pad.

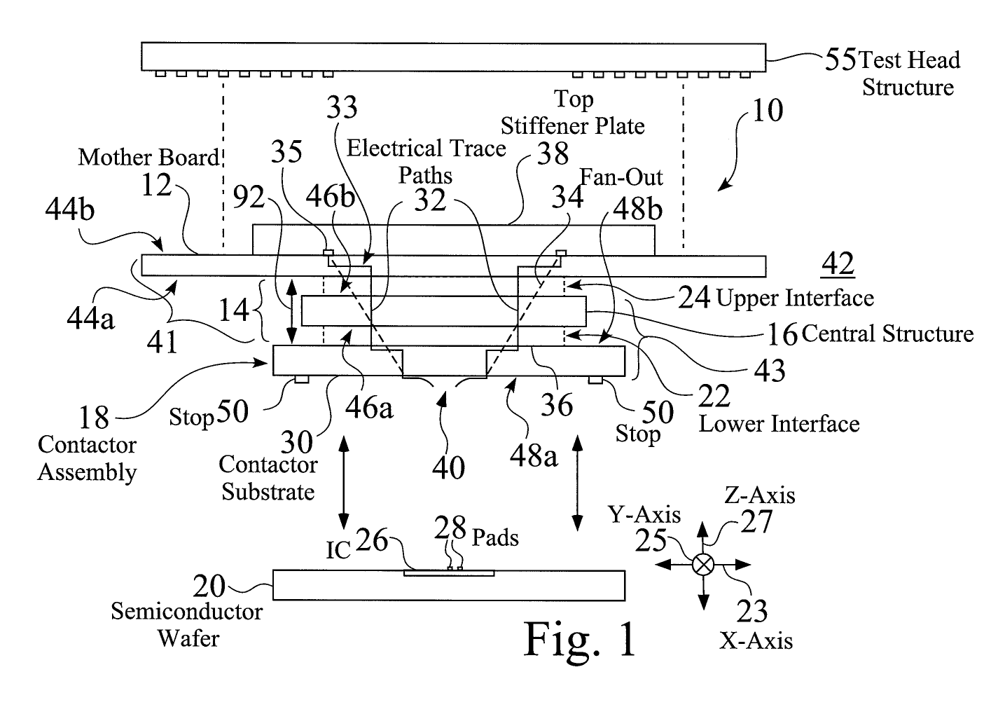

FIG. 1 is a detailed schematic diagram 10 of a probe card assembly 42 that is connectable to a test head structure 55. As seen in FIG. 1, the probe card assembly 42 may comprise an upper probe card interface assembly (PCIA) 41 and a contactor assembly 18, wherein the upper probe card interface assembly (PCIA) 41 comprises a motherboard 12 having electrical connections 33 extending there through, and an integrated contactor mounting system 14.

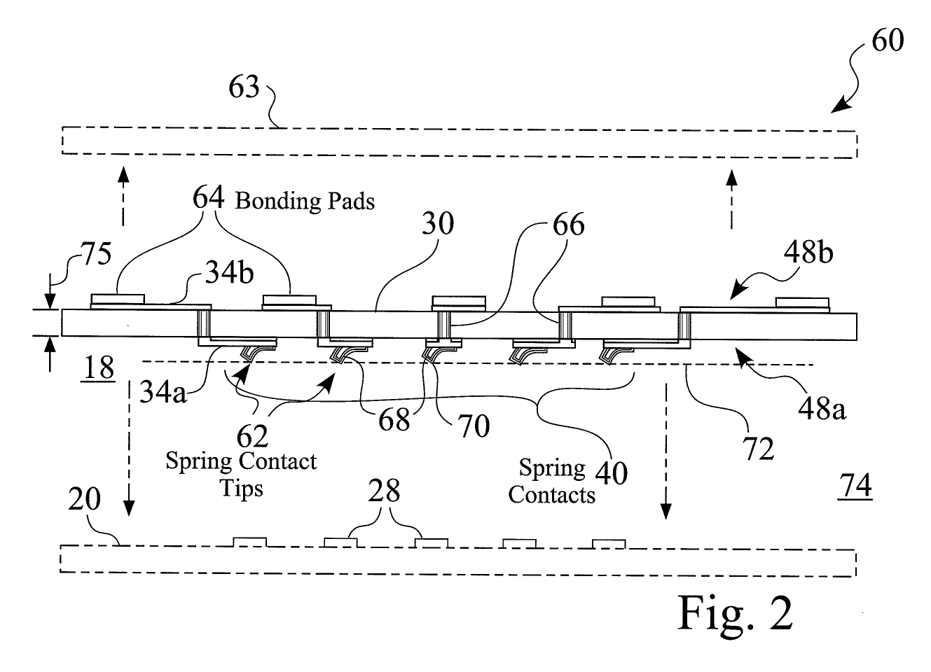

As seen in FIG. 1, the probe card assembly 42 may alternately comprise a lower probe card interface assembly (LPCIA) 43 connected to the mother board 12, wherein the lower probe card interface assembly (LPCIA) 43 comprises the contactor assembly 18 having electrical connections 66 (FIG. 2) extending there through, and a connected central structure 16, which is then connectable to the motherboard 12 through the upper interface 24.

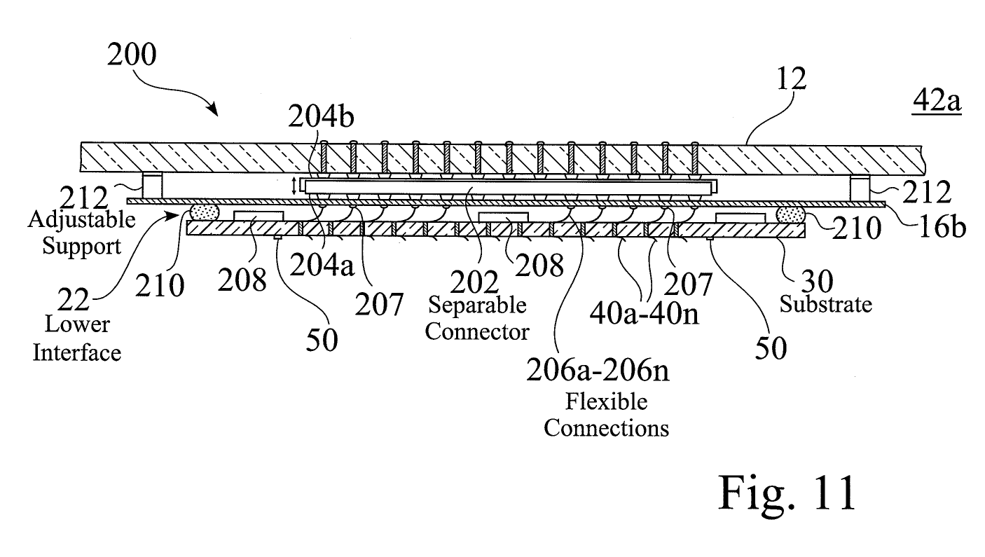

As further seen in FIG. 1, electrical trace paths 32 extend through the motherboard 12, the contactor mounting system 14, and the contactor assembly 18, to spring contacts, i.e. spring probes 40, such as to establish contacts with pads 28 on one or more ICs 26 on a semiconductor wafer 20. Fan-out 34 may preferably be provided at any point for the electrical trace paths 32 in a probe card assembly 42 (or in other embodiments of the systems disclosed herein), such as to provide transitions between small pitch components or elements, e.g. contactor assemblies 18, and large pitch components or elements, e.g. tester contact pads 35 on the mother board 12. For example, fan-out may typically be provided by the mother board 12, by the contactor assembly 18, by a central structure 16, e.g. a Z-block 16, by an upper interface 24 comprising a motherboard Z-Block or one or more separable connectors 202 (FIGS. 11, 12, 14 and 17), or anywhere within the lower interface 22 and/or the upper interface 24.

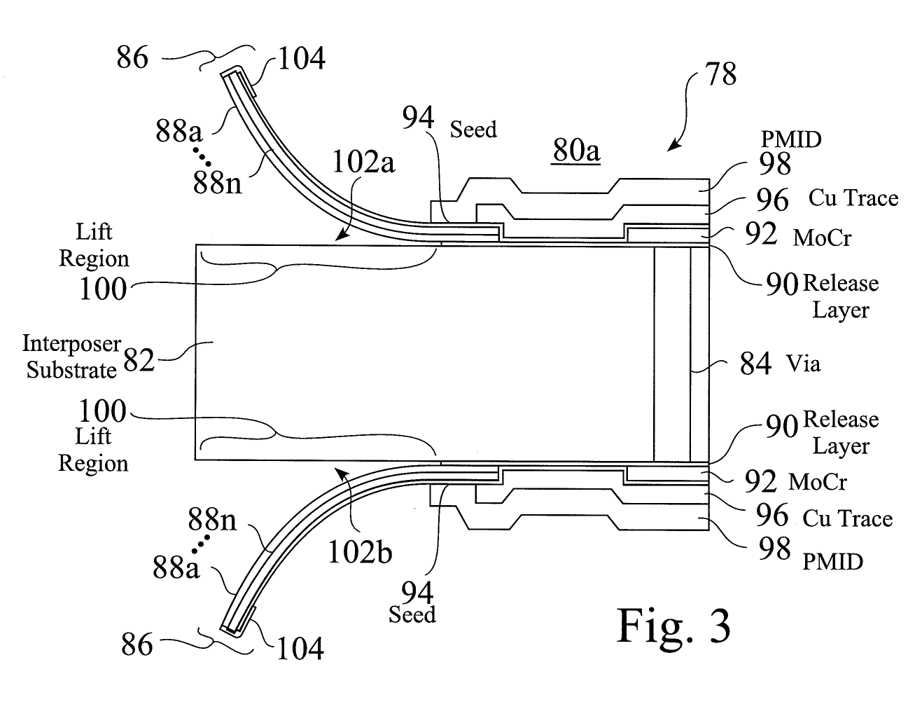

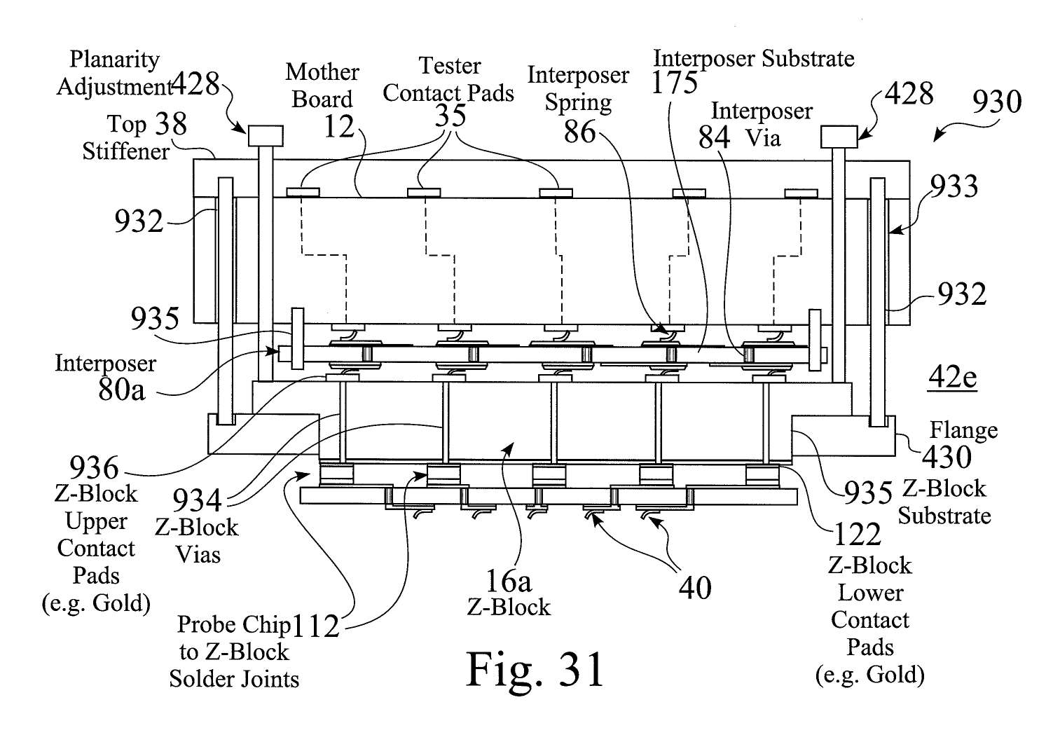

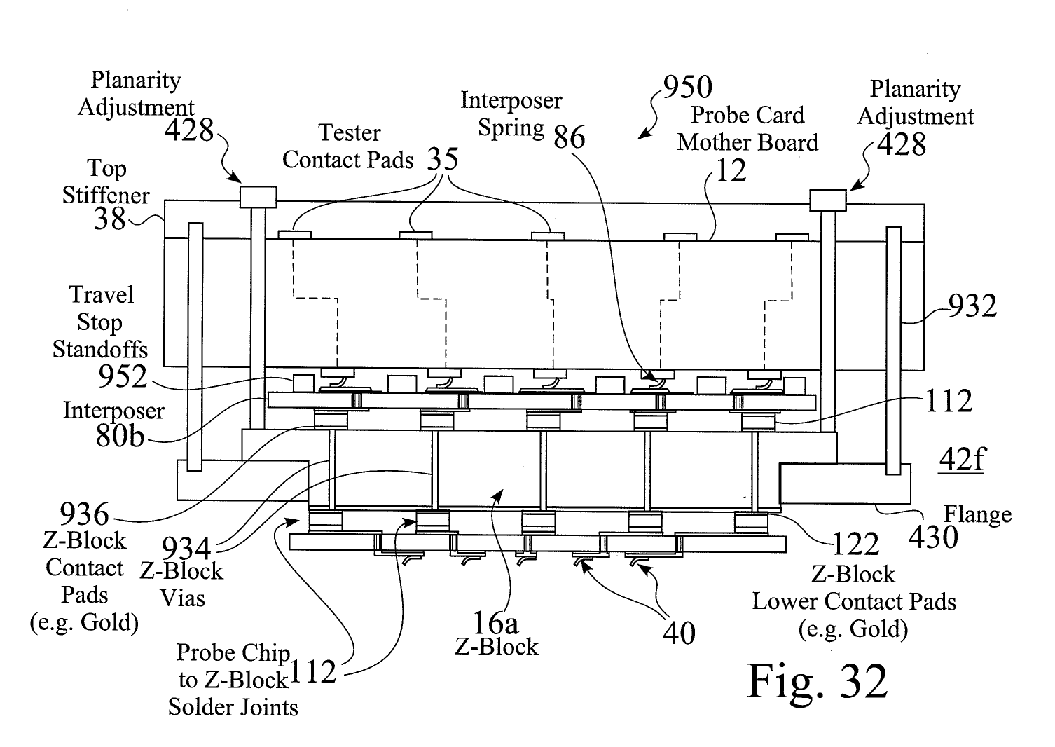

As also seen in FIG. 1, the contactor mounting system 14 typically comprises a central structure 16, e.g. a Z-block 16a or a daughter card 16b, a lower interface 22 between the central structure 16 and the contactor substrate 30, and an upper interface 24 between the central structure 16 and the motherboard 12. In some probe card assemblies 42, the lower interface 22 comprises a plurality of solder bonds 112 (FIG. 4). As well, in some quick-change probe card assemblies 42, the upper interface 24 comprises a combination of componentry and connections, such as an interposer 80, e.g. 80a (FIGS. 3 and 31) or 80b (FIG. 32), separable connectors 202, solder bonds and/or a motherboard Z-block.

Additionally, optical signals can be transmitted through the contactor substrate 30, by fabricating openings of sufficient size through the substrate through which the optical signals can be transmitted. The holes may be unfilled or filled with optically conducting materials, including but not limited to polymers, glasses, air, vacuum, etc. Lenses, diffraction gratings and other optical elements can be integrated to improve the coupling efficiency or provide frequency discrimination when desired.

FIG. 2 is a detailed schematic view 60 of a contactor assembly 18, in which the non-planar portions of compliant spring probes 40 are preferably planarized and/or plated. As seen in FIG. 2, a contactor assembly 18 comprises a contactor substrate 30 having a probing surface 48a and a bonding surface 48b opposite the probing surface 48a, a plurality of spring probes 40 on the probing surface 48a, typically arranged to correspond to the bonding pads 28 (FIG. 1) of an integrated circuit 26 on a semiconductor wafer 20, and extending from the probing surface 48a to define a plurality of probe tips 62, a corresponding second plurality of bonding pads 64 located on the bonding surface 48b and typically arranged in the second standard configuration, and electrical connections 66, e.g. vias, extending from each of the spring probes 40 to each of the corresponding second plurality of bonding pads 64.

While the contacts 40 are described herein as spring contacts 40, for purposes of clarity, the contacts 40 may alternately be described as contact springs, elastic core members, spring probes or probe springs.

Preferred embodiments of the spring contacts 40 may comprise either non-monolithic micro-fabricated spring contacts 40 or monolithic micro-fabricated spring contacts 40, depending on the application. Non-monolithic micro-fabricated spring contacts utilize one or more mechanical (or micro-mechanical) assembly operations, whereas monolithic micro-fabricated spring contacts utilize batch mode processing techniques including but not limited to photolithographic processes such as those commonly used to fabricate MEMs devices and semiconductor integrated circuits.

In some embodiments of the spring contacts 40, the electrically conductive monolithically formed contacts 40 are formed in place on the contactor substrate 30. In other embodiments of the spring contacts 40, the electrically conductive monolithically formed contacts 40 are formed on a sacrificial or temporary substrate 63, and thereafter are removed from the sacrificial or temporary substrate 63, e.g. such as by etchably removing the sacrificial substrate 63, or by detaching from a reusable or disposable temporary substrate 63, and thereafter affixing to the contactor substrate 30.

Both non-monolithic and monolithic micro-fabricated spring contacts can be utilized in a number of applications including but not limited to semiconductor wafer probe cards, electrical contactors and connectors, sockets, and IC device packages.

Sacrificial or temporary substrates 63 may be used for spring fabrication, using either monolithic or non-monolithic processing methods. Spring contacts 40 can be removed from the sacrificial or temporary substrate 63 after fabrication, and used in either free standing applications or in combination with other structures, e.g. contactor substrate 30.

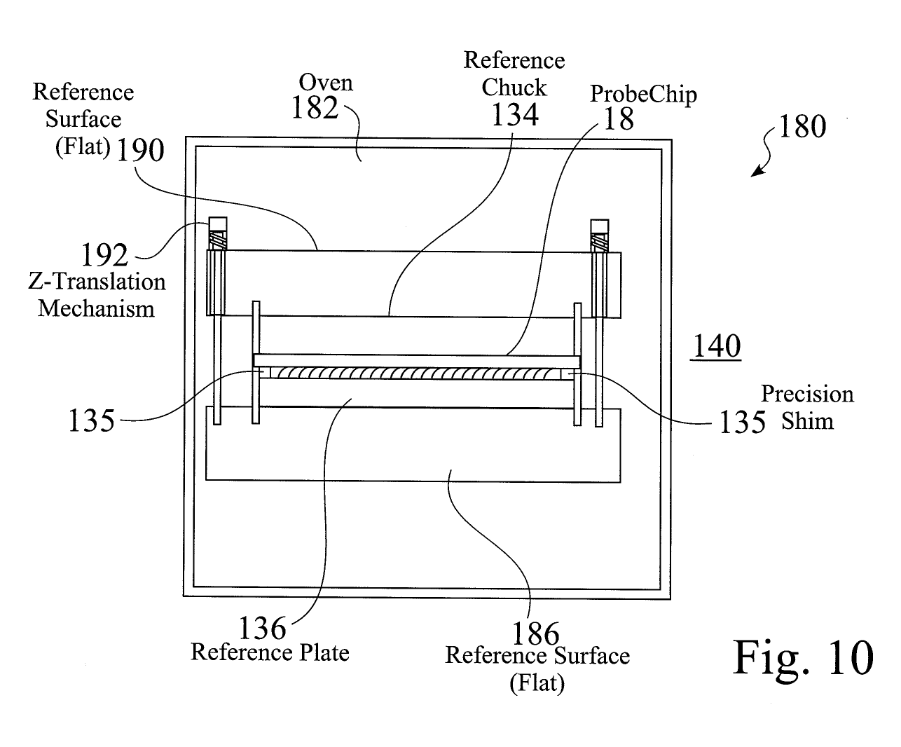

In embodiments of contactor assemblies that are planarized, a plane 72 of optimum probe tip planarity is determined for a contactor assembly 18 as fabricated. Non-planar portions of spring contacts 40 located on the contactor substrate 30 are preferably plated 68, and are then planarized, such as by confining the probes 40 within a plane within a fixture 140 (FIG. 10), and heat treating the assembly. The non-planar portions of the spring probes 40 may also be plated after planarization, to form an outer plating layer 70.

The contactor assembly 18 shown in FIG. 2 further comprises fan-out 34, such as probe surface fan-out 34a on the probe surface 48a of the contactor substrate 30 and/or rear surface fan-out 34b on the bonding surface 48b of the contactor substrate 30.

Monolithic micro-fabricated spring contacts 40, such as seen in FIG. 2, comprise a unitary, i.e. integral construction or initially fabricated using planar semiconductor processing methods, whereas non-monolithic spring contacts are typically assembled from separate pieces, elements, or components. Non-monolithic or monolithic micro-fabricated spring contacts can be fabricated on one or both sides of rigid or flexible contactor substrates having electrically conductive through-vias and multiple electrical signal routing layers on each side of the substrate to provide electrically conductive paths for electrical signals running from spring contacts on one side of the substrate to spring contacts or other forms of electrical connection points on the opposite side of the substrate through signal routing layers on each side of the substrate and one or more electrically conductive vias fabricated through the substrate.

An exemplary monolithic micro-fabricated spring contact comprising a stress metal spring i.e. an elastic core member, is fabricated by sputter depositing a titanium adhesion/release layer having a thickness of 1,000 to 5,000 angstrom on a ceramic or silicon substrate (approximately 10-40 mils thick) having 1-10 mil diameter electrically conductive vias pre-fabricated in the substrate. Electrically conductive traces fabricated with conventional photolithographic processes connect the spring contacts to the conductive vias and to the circuits to which they ultimately connect. A common material used to fabricate stress metal springs is MoCr, however other metals with similar characteristics, e.g. elements or alloys, may be used. An exemplary stress metal spring contact is formed by depositing a MoCr film in the range of 1-5 mm thick with a built-in internal stress gradient of about 1-5 GPa/mm. An exemplary MoCr film is fabricated by depositing 2-10 layers of MoCr, each layer about 0.2-1.0 mm thick. Each layer is deposited with varying levels of internal stress ranging from up to 1.5 GPa compressive to up to 2 GPa tensile.

Individual micro-fabricated stress metal spring contact “fingers” are photolithographically patterned and released from the substrate, using an etchant to dissolve the release layer. The sheet resistance of the finger and its associated trace can be reduced by electroplating with a conductive metal layer (such as copper, nickel, or gold). The force generated by the spring contact can be increased by electrodepositing a layer of a material, such as nickel, on the finger to increase the spring constant of the finger. In interposer applications (see FIG. 3), the quality of the electrical contact may optionally be improved by electrodepositing depositing a material 104, such as Rhodium, onto the tip 86 through a photomask, prior to releasing the finger from the substrate.

The lift height of the spring contacts is a function of the thickness and length of the spring and the magnitude of the stress gradient within the spring. The lift height is secondarily a function of the stress anisotropy and the width of the spring and the crystal structure and stress in the underlying stress metal film release layer. The spring constant of the spring is a function of the Young's modulus of the material used to fabricate the spring and the length, width, and thickness of the spring. The spring constant of the spring can be increased to the degree desired by enveloping the springs 40 with one or more electrodeposited, sputtered, or CVD metal coatings (see FIGS. 1,2). Coatings can be applied with thicknesses of between 1 micron and 100 microns using metals including nickel, gold, palladium, platinum, rhodium, tungsten, cobalt, iron, copper, and combinations thereof. The spring constant can be varied by controlling the thickness of the deposited coating layers, the geometrical characteristics of the spring, the choice of metal, and the number of coatings.

The microstructure and hence mechanical properties of the resulting spring contacts are a function of the metals deposited as well as the deposition and subsequent processing conditions. The process conditions for fabricating spring contacts according to the present invention comprise, electrodeposition current densities in the range of about 0.3 to about 30 Amperes/square decimeter (typically 3 Amperes per square decimeter) and saccharine added at a concentration of greater than about 1 gram/liter or preferably greater than 4.5 grams per liter. One or more heat treatment processes are preferably included, such as to provide any of probe tip planarization relative to the support substrate and/or annealment to provide increased resistance to set and cracking through repeated cycles of deflection over the life of the spring contact.

Grain sizes for spring coating or plating layers, e.g. 68,70 (FIG. 2), such as comprising nickel coatings 68,70 fabricated using the above conditions may typically range from about 200 nm to about 400 nm, e.g. as measured by SEM cross sections, but may range from as low as about 100 nm to about 500 nm before the anneal processing step. After the annealing processing step, the grain sizes typically grow to larger than about 400 nm, and may even exceed about 1000 nm.

It should be noted that methods for depositing coatings of both insulating and conductive materials are discussed in Yin et al., Scripta mater: 44(2001) 569-574; Feenstra, et al, Materials Science and Engineering: A, Volume 237, Number 2, September 1997, pp. 150-158(9); Kumar et al., Acta Materialia 51 (2003) 387-405), and patent publications, such as U.S. Pat. No. 6,150,186. Electrodeposited layers of metals such as nickel and nickel alloys such as Nickel Cobalt are characterized as having “nanocrystalline” microstructures when the grain sizes range from less than a few tens of nanometers to an extreme upper limit of 100 nm. From this description, the materials fabricated as described above would not be characterized as having nanocrystalline microstructures.

Setting, i.e. plastic deformation, of the probes during the useful life of the product can be minimized by carrying out an annealing process at an optimal time and temperature. For example, using a 250 C anneal temperature, it was observed that a minimum set occurred for a 3 hour anneal (5 microns) whereas for 1 hour and 12 hours annealing times, set was observed to be 28 microns and 12 microns respectively. Additionally, accelerated aging studies, i.e. repeated, cycling of the spring probes on a probe card using a wafer prober have shown that the spring contacts are resistant to cracking when fabricated with an anneal time selected to reduce set such as for the annealing process described above. However, it has also been observed that resistance to cracking decreases with anneal times in excess of that required to minimize set.

The above teachings describe the manufacture of an exemplary monolithic micro-fabricated stress metal spring, however, those skilled in the art will understand that spring contacts having the characteristics required to practice the present invention can provide many possible variations in design and/or fabrication processes. Such variations may include but would not be limited to, for example, choice of processes, process chemicals, process step sequence, base spring metal, release layer metal, coating metals, spring geometry, etc. The structures and processes disclosed herein may preferably be applied to a wide variety of non-monolithic spring contacts and monolithic micro-fabricated spring contacts, such as but not limited to spring structures disclosed in D. Smith and A. Alimonda, Photolithographically Patterned Spring Contact, U.S. Pat. No. 6,184,699; M. Little, J. Grinberg and H. Garvin, 3-D Integrated Circuit Assembly Employing Discrete Chips, U.S. Pat. No. 5,032,896; M. Little, Integrated Circuit Spring Contacts, U.S. Pat. No. 5,663,596; M. Little, Integrated Circuit Spring Contact Fabrication Methods, U.S. Pat. No. 5,665,648; and/or C. Tsou, S. L. Huang, H. C. Li and T. H. Lai, Design and Fabrication of Electroplating Nickel Micromachined Probe with Out-of-Plane Deformation, Journal of Physics: Conference Series 34 (2006) 95-100, International MEMS Conference 2006.

FIG. 3 is a partial cross sectional view 78 of an interposer structure 80, such as for a dual-sided interposer 80a, Similar construction details are preferably provided for a single-sided interposer.

Interposer springs 86, such as photolithographically formed probe springs 86, are generally arranged within an interposer grid array, to provide a plurality of standardized connections. For example, in the dual-sided interposer 80a shown in FIG. 31, the interposer springs 86 provide connections between a motherboard 12 and a Z-block 16a. Similarly, in a single-sided interposer 80b, such as seen in FIG. 32, the interposer springs 86 provide connections between a motherboard 12 and the interposer 80b.

Electrically conductive interposer vias 84 extend through the interposer substrate 82, from the first surface 102a to the second surface 102b. The interposer vias 84 may preferably be arranged in redundant via pairs, such as to increase the manufacturing yield of the interposer 80, and/or to promote electrical conduction, particularly for power traces.

The opposing surfaces 102a,102b are typically comprised of a release layer 90, such as comprising titanium, and a composite layer 88,92, typically comprising a plurality of conductive layers 88a-88n, having different inherent levels of stress. Interposer vias 84, e.g. such as CuW, PtAg, or gold filled, extend through the central substrate 82, typically ceramic, and provide an electrically conductive connection between the release layers 90.

The composite layers 88,92 typically comprise MoCr (however other metals with similar characteristics, e.g. elements or alloys, may be used), in which the interposer probe springs 86 are patterned and subsequently to be released within a release, i.e. lift, region 100. For example, while composite layers 88a-88n for spring probes 40 or interposer springs 86 may typically comprise MoCr, other alloys, such as comprising TiNi or CrNi, may be used for one or more of the layers 88a-88n, such as to reduce trace resistance.

In some embodiments, a seed layer 94, such as a 0.5 to 1 μm thick gold layer, is preferably formed over the composite layers 88,92. In some embodiments, a tip coating 104, such as rhodium or palladium alloy, is controllably formed at least over the tips of spring fingers 86, such as to provide wear durability and/or contact reliability. Traces 96, typically comprising copper (Cu), are selectably formed by plating over the structure 78, as shown, such as to provide reduced resistance. As well, polyimide PMID layers 98 are typically formed over the structure 78, as shown, to define the spring finger lift regions. The seed layer 94 seen in FIG. 3, such as comprising a thick layer of gold, remains on the lifted fingers 86, to reduce sheet resistance of the fingers 86.

Enhanced Lower Interface Structures and Associated Processes. In regard to the exemplary probe card assembly 42 seen in FIG. 1, a variety of enhancements can be made to the structures and/or processes associated with the lower interface 22 between the contactor assembly 18 and the central structure 16, e.g. comprising any of a Z-Block 16a or a daughter card 16b.

For example, it would be advantageous to provide adequate spacing between a probe chip contactor assembly 18 and a central structure 16, such as to allow mounting 124 (FIG. 4) of attached components 122 (FIG. 4) to the back surface 48b of the probe chip contactor assembly 18, and/or to the first surface 46a of a central structure 16, e.g. a Z-lock 16a or daughter card 16b. In some embodiments, the attached components 122 may comprise any of capacitors, resistors, inductors, and/or active semiconductor components.

FIG. 4 is a partial schematic cutaway view 110 of exemplary enhanced solder connection structures 112 between planar components, e.g. between a probe chip substrate 30 and a Z-block 16a, such as to provide an increased gap 120 between the probe chip contactor assembly 18 and the Z-Block 16a. The exemplary solder connection structures 112 seen in FIG. 4 allow components to be attached to the back surface 48b of the probe chip contactor assembly 18, within the gap 120, or to the first surface 46a of the Z-Block 16a. As well, some embodiments of the enhanced solder connection structures 112 resist shorts at tight connection pitches.

As seen in FIG. 4, solutions may comprise any of two layers of solder 114 and 116; three layers solder 114a, 114b, and 116; and/or solder columns 118. For example, an exemplary two layer solder bond 112 is seen in FIG. 4, wherein a first layer 114 is screened onto one of the substrates 16 or 30, e.g. the Z-block 16a, and a second solder 116 having a lower melting temperature than the first solder 114, completes the electrical connection between the Z-block 16 and the probe chip substrate 30.

As also seen in FIG. 4, three layers of solder 114a,114b, and 116 may be used to provide electrical connections between substrates, such as between the Z-block 16a and the probe chip contactor assembly 18. An intermediate solder connection 116 is located between solder regions 114a,114b located on opposing substrates 30,16, wherein the intermediate solder connection 116 has a lower melting temperature than either of the outer solder regions 114a,114b.

The size of the solder balls 116 may preferably be optimized between shorts (too large) and opens (too small) for a given pad size 64,122, pad to pad spacing, and/or Z tolerance (gap thickness variation between the first surface 46a of the Z-block 16a and the back surface 48b of the probe chip contactor assembly 18. In some solder connection embodiments 112, an exemplary solder material chosen for low temperature soldering processes 116 comprises BiSnAg, wherein the solder balls 116 are reflowed to form bumps on the Z-block 16a and/or probe chip backside metal 64.

As further seen in FIG. 4, one or more solder columns 118 can provide solder connections between substrates, e.g. between a probe chip contactor assembly 18 and a central structure 16, e.g. a Z-block 16a or a daughter card 16b. Preformed solder columns 118 provide a way to capture, position, and align an array of solder columns 118 between the Z-Block 16a and the probe chip contactor assembly 18.

The preformed array of solder columns 118 can be provided with a laminate wafer 119, comprising a soluble material, that dissolves after assembly. The solder columns 118, such as available through Six Sigma, Inc., of Milpitas, Calif., may preferably comprise a structure, such as but not limited to an outer shell or coil, and an inner solder region, which when heated to form soldered connections 112 between the probe chip contactor assembly 18 and a central structure 16, retains planarity between the two substrates 30 and 16, and controllably defines a gap 120. The solder columns 118 can be provided by a wide variety of structures and methods such as but not limited to:
a separate matrix of columns 118 that is placed between a probe chip substrate 30 and a Z-block 16b, and is then solderably affixed to both substrates 30,16 at the same time;
a plurality of columns 118 that are preformed or attached to the back surface 48a of the probe chip substrate 30 and subsequently bonded or soldered to the first surface 46a of the Z-block 16a; or
a plurality of columns 118 that are preformed or attached to the first surface 46a of the Z-block 16a and subsequently bonded or soldered to the back surface 48a of the probe chip substrate 30.

The use of solder columns 118 between substrates may attain a greater range of standoff height 120 and tighter pitch, as compared to probe chip to Z-block structures 43 that use solder balls 112, such as to increase yield. For example, if planarizing a front surface 48a of a contactor assembly 18, the height of solder columns 118 may provide a smaller pitch, e.g. for solder columns 118 that tend to expand less than a solder ball 112 for a given height 120.

The exemplary Z-block solder pads 122 seen in FIG. 4 may preferably comprise any of titanium (Ti), e.g. 1000 A thick, nickel (Ni), e.g. 12,000 A thick, gold (Au) e.g. 4,000 A thick, or any combination thereof. Z-block solder pads 122 that comprise nickel (Ni) or gold (Au) may preferably be made relatively thick e.g. greater than about 10,000 A for nickel and greater than 6,000 A for gold (Au), such as to enable multiple rework cycles.

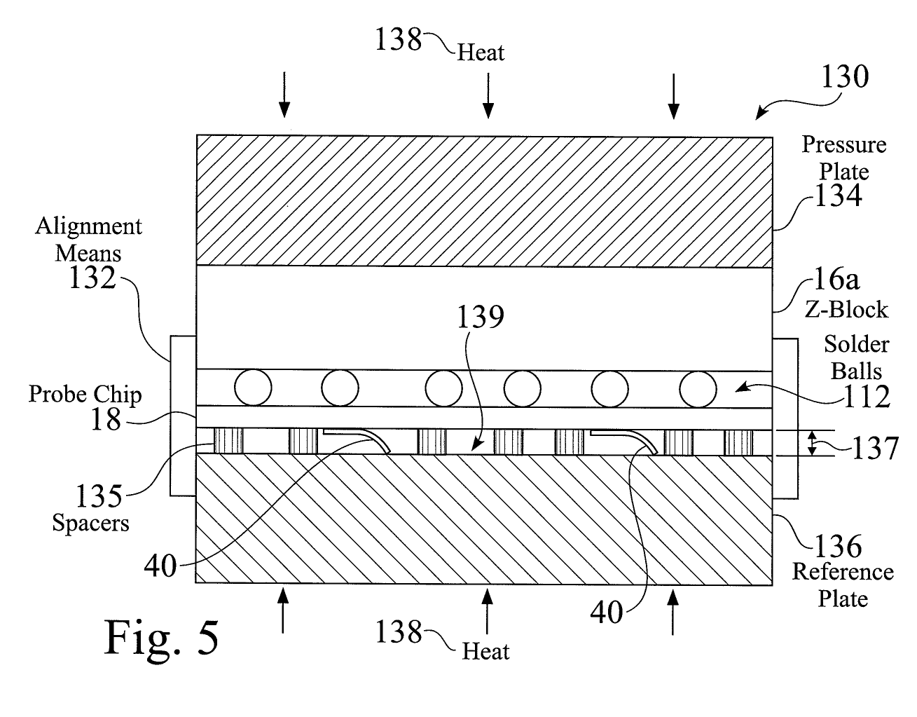

Probe Chip to Z-block Solder Fixture. FIG. 5 is a partial schematic view of a fixture 130 for assembling a lower probe card interface assembly (LPCIA) 43, to solderably attach a probe chip contactor 30 to a central structure 16, e.g. a Z-Block 16a.

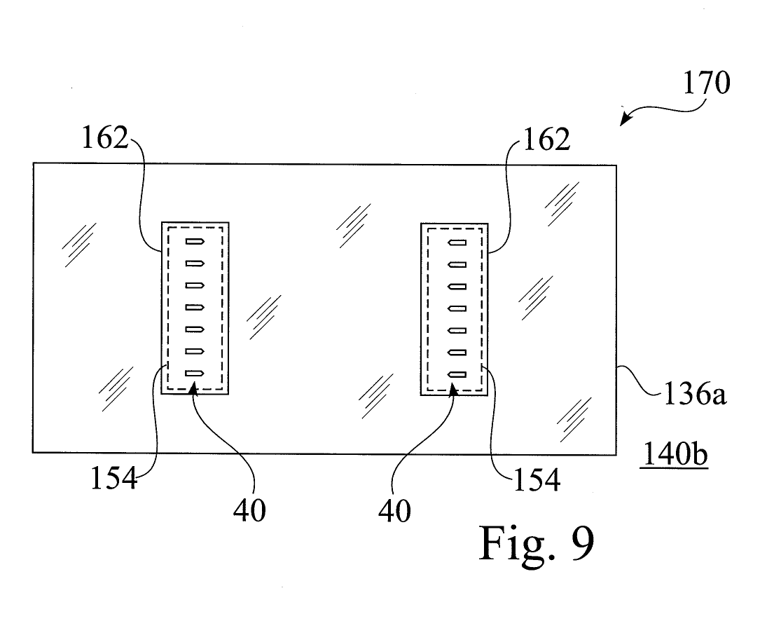

As seen in FIG. 5, a plurality of spacers 135 having a defined height 137 are distributed over a planar surface of a reference plate 136. The distributed spacers 135 between the front surface 48a of the probe contactor 30 and the planar surface 139 of a reference plate 136 provides a precise spacing 137 by which subsequent thermal processing 138 can act upon the lower probe card interface assembly (LPCIA) 43 to form the solder junctions 112, without a need for a custom reference plate 136a (FIG. 9) that includes precision wells 162 having specific depth 164 and location upon the plate 136a.

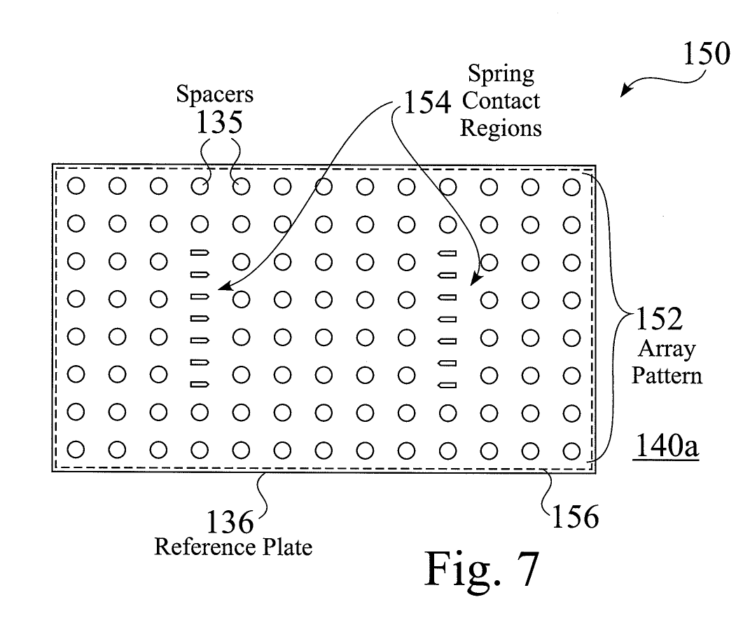

The distributed spacers 135 typically comprise any of shim dots 135, e.g. cylinders 135, having a precise height 137, or spheres 135 having a precise diameter 137, which eliminates the need for custom fabricated reference plate for a probe chip to Z-block solder fixture 130. In some embodiments, the distributable spacers comprise any of metal, ceramic, glass, and a semiconductor. The distributed spacers 135 take up fluctuations in substrate thickness that would otherwise be transmitted to the back side 48b of the probe chip contactor assembly 18. The spacers 135, e.g. shim dots or spheres are typically aligned using a stainless steel stencil 156 (FIG. 7), in a similar manner that spacers 135 may also be used within a planarization fixture and process, e.g. fixture 140a (FIG. 7).

As seen in FIG. 5, an alignment means 132 aligns the Z-block 16a and the probe chip contactor assembly 18, between a pressure plate 134 and the reference plate 136, and then the assembly 43 is heated 138 to reflow the solder 112, which may preferably comprise the enhanced solder connections 114,116 or solder columns 118, as discussed above.

The reference plate 136 shown in FIG. 5 may preferably comprise a universal reference plate, that may be the same, i.e. universal, for different probe chips (e.g. planar, with no recess details), since the spacers 135, typically comprising shim dots or spheres 135, provide a controlled spacing 137 between the front surface 48a of the probe chip and the reference plate 136.

As noted above, the spacers 135 may preferably comprise distributed shims, e.g. shim dots 135, which in some embodiments comprise shim dots that are laser cut from shim stock.

Enhanced Structures and Processes for Planarization. For many embodiments of probe card assemblies 42, it is advantageous to planarize the probe springs 40, by providing controlled thermal processing of the probe chip contactor 30.

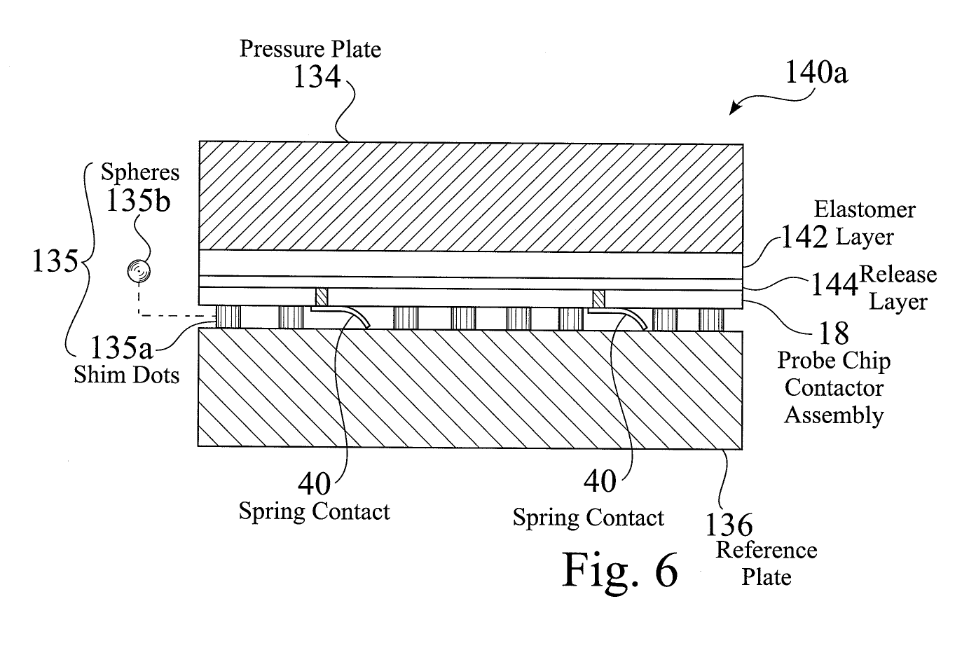

FIG. 6 is a partial schematic cutaway view of a planarization fixture 140a with a flat reference plate 136 and using spacers 135, such as comprising shim dots 135a or spheres 135b. FIG. 7 is a schematic plan view of a planarization fixture 140a with a flat reference plate 136 and using spacers 135, comprising shim dots and/or spheres. The shim dots or spheres 135 shown in FIG. 6 and FIG. 7 may preferably be positioned, e.g. surrounding one or more spring contact regions 154, such as by a stencil 156 aligned with the reference plate 136. In some embodiments, the stencil 156 comprises stainless steel.

The shim dots or spheres 135 eliminate the need for a custom fabricated reference plate for a probe chip planarization fixture 140a. The distributable spacers 135, e.g. shim dots or spheres, may typically comprise any of metal, ceramic, glass, and a semiconductor. In some embodiments, the shim dots or spheres 135 comprise a magnetic material, so that they stick to the reference plate 136, which can also be at least partially comprised of a magnetic material, such as steel or iron, or may alternately comprise other attached or associated means for creating magnetic attraction to the reference plate 136, e.g. an electromagnetic element or field embedded within a stainless steel reference plate 136.

As seen in FIG. 6, when the probe chip contactor assembly 18 is positioned in the fixture 140a to be planarized, the back surface 48b is constrained by a pressure plate. As well, an elastomeric layer 142, e.g. such as comprising silicone, is typically located between the back surface 48b of the probe chip contactor assembly 18 and the pressure plate 134, such as to compensate for variations in the back surface 48b of the probe chip contactor assembly 18, e.g. such as due to any of traces, bonding pads, and release regions. In addition, a release layer 144 is typically used between the elastomeric layer 142 and the back surface 48b of the probe chip contactor assembly 18, such as to prevent adhesion between the elastomeric layer 142 and the back surface 48b during thermal processing.

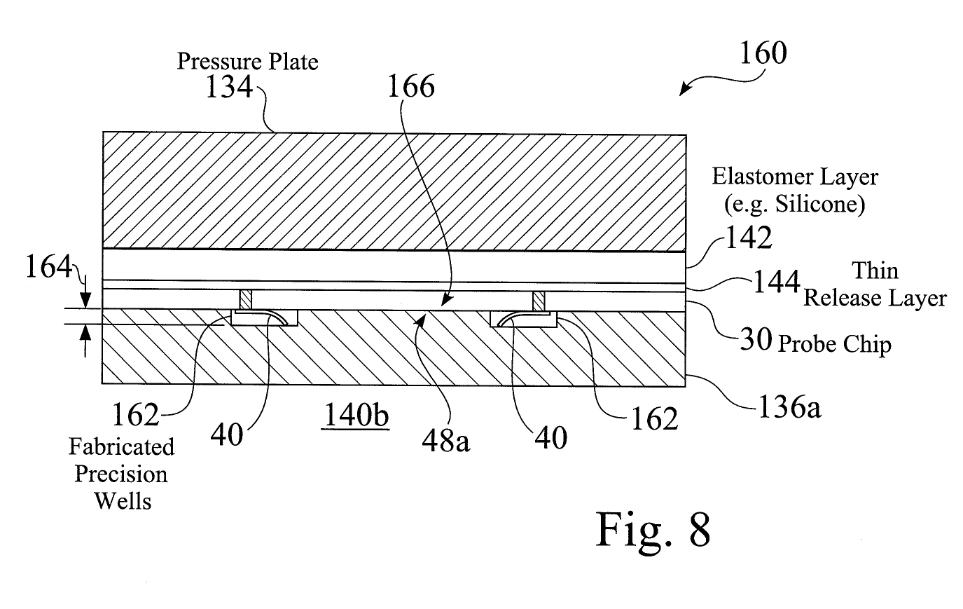

FIG. 8 is a partial schematic cutaway view 160 of a planarization fixture 140b with fabricated precision wells 162 defined in a flat reference plate 136a. FIG. 9 is a schematic plan view 170 of a planarization fixture 140b with fabricated precision wells 162 defined in a flat reference plate 136a. The reference plate 136a shown in FIG. 8 and FIG. 9 comprises one or more custom precision wells 162, such as to specifically correspond to spring probe regions 154 of a probe chip contactor 30 that is controllably placed on the reference plate 136a for a planarization process. For example, the front surface 48a of the probe chip 30 is controllably held flat, such as by the pressure plate 134, against the main surface 166 of the reference plate 136a, and spring tip planarity is determined by the depth 164 of the fabricated precision wells 162.

Therefore, for most embodiments of the planarization fixture 140b, each of the wells 162 typically are required to have a nearly identical depth 164, which may be hard to fabricate. As well, different reference plates 136a are typically required to be provided for different probe chip contactor assemblies 18, which typically have different layouts, e.g. probe spring areas 154 and spring depths 164. Therefore, the alternate planarization fixture 140a, using a more universal planar reference plate 136 and spacers 135 with different heights and/or distribution patterns, may provide advantages over a more specific planarization fixture design 140b.

As seen in FIG. 8, when the probe chip contactor assembly 18 is positioned in the fixture 140b to be planarized. The back surface 48b of the probe chip substrate 30 is constrained by a pressure plate 134. In a similar manner to the planarization fixture 140a and associated process, an elastomeric layer 142, e.g. such as comprising silicone, is typically located between the back surface 48b of the probe chip contactor assembly 18 and the pressure plate 134, such as to compensate for variations in the back surface of the probe chip contactor assembly 18, e.g. such as due to any of traces, bonding pads, and release regions. In addition, a release layer 144 is typically used between the elastomeric layer 142 and the back surface 48b of the probe chip contactor assembly 18, such as to prevent adhesion between the elastomeric layer 142 and the back surface 48b during thermal processing.

Planarization Structures and Processing. FIG. 10 is a schematic view 180 of an exemplary planarization fixture 140 for planarization of spring structures, such as for various embodiments of probe chip contactor assemblies 18.

For example, the controlled processing of spring structures can improve co-planarity of the plated metal probe tips 40, e.g. stress metal springs 40, of a probe chip assembly 18. The probe chip substrate 30 is held flat against the flat surface of a reference chuck 134, e.g. such as a vacuum or electrostatic chuck 134. In the exemplary embodiment shown in FIG. 10, a plurality of precision shims 135 are placed on the surface at the periphery of the probe chip substrate 30, and rest upon a flat substrate 136, e.g. glass 136, which is located on a lower flat reference surface 186. A flat reference surface 190 is placed on top of the upper reference chuck 134 and the distributed shims 135, thus compressing the spring probes 40, such that the probe tips 40 are located at exactly the same height relative to the back side 48b of the probe chip substrate 30. In one planarization process embodiment, the assembly 30 is then heated in the oven 182 to between about 175 degrees Centigrade to about 225 degrees Centigrade for a time period of between about 1 hour to about 3 hours, to allow the spring probes 40 to anneal and conform to the flat and planar reference surface 136,186. The system 140 is then slowly cooled, such as to optimally relieve stresses generated by the difference in the coefficients of thermal expansion between the ceramic substrate 30 and the probe chip plating layers, e.g. 68,70.

In an alternative embodiment, the probe tips 40 are made parallel to the front surface 48a of the probe chip substrate 30, by replacing the glass substrate 136 with a chuck 136 having a flat surface and one or more recesses 162 (FIG. 9), for the spring probes 40, wherein recesses 162 are fabricated with a precise depth 164. The front surface 48a of the substrate 30 is then held flat against the chuck flat surface 136, and the spring probes 40 are compressed against the lower surface of the recesses 162. This method of planarization minimizes the effect of variation in the thickness of the substrate 30 and compression of the spring probes 40. The method also helps to maintain coplanarity of the probe tips 62, after subsequent processing steps. For example, variations in substrate thickness 30 can decrease probe tip planarity after solder bonding, if the probe chip contactor assembly 18 is held flat against its front surface 48a during bonding if it was held flat against its back surface 48b during probe tip planarization.

Probe Assemblies Having Separable Connectors. FIG. 11 is a cross-sectional view 200 of a suspended probe card assembly 42a having an intermediate, i.e. central structure 16, e.g. an intermediate daughter card 16b, that is detachably connectable to the mother board 12 by a separable connector 202. The exemplary lower interface 22 shown in FIG. 11 comprises flexible connections 206a-206n are preferably made with springs, e.g. probe springs 40, and provide both electrical connections to the daughter card 16b, as well as a mechanical connection between the probe chip contactor assembly 18 and the daughter card 16b. In the probe card assembly 42a, the flexible connections 206a-206n are permanently connected to conductive pads 207 on the daughter card 16b, using either solder or conductive epoxy. The flexible connections 206a-206n are preferably designed to provide a total force larger than that required to compress all the bottom side probe springs 40a-40n fully, when compressed in the range of 2-10 mils. As well, the flexible connections 206a-206n are preferably arranged, such that the probe chip substrate 30 does not translate in the X, Y, or Theta directions as the flexible connections 206a-206n are compressed.

Upper substrate standoffs 208 are preferably used, to limit the maximum Z travel of the probe chip substrate 30, relative to the daughter card 16b, thereby providing protection for the flexible connections 206a-206n. The upper standoffs 208 may preferably be adjustable, such that there is a slight pre-load on the flexible connections 206a-206n, forcing the probe chip substrate 30 away from the daughter card 16b, thereby reducing vibrations and chatter of the probe chip substrate 30 during operation. As well, one or more standoffs 208, connected to either the back surface 48b of the probe chip contactor 18 or the opposing first side 46a of the daughter card 16b, may be substantially located in a central region of either the probe chip contactor 18 or the daughter card 16b, such as for pre-load or to prevent excessive bowing between the two substrates 30,16b.

A damping material 210, e.g. such as a gel, may also preferably be placed at one or more locations between the probe chip substrate 30 and the daughter card 16b, to prevent vibration, oscillation or chatter of the probe chip substrate 30.

The separable connector 202, e.g. such as an FCI connector 202, preferably has forgiving mating coplanarity requirements, thereby providing fine planarity compliance between the daughter card 16b and the mother board 12. A mechanical adjustment mechanism 212, e.g. such as but not limited to fasteners 216, spacers 214, nuts 218, and shims 220 (FIG. 11), may also preferably be used between the daughter card 16b and the mother board 12.

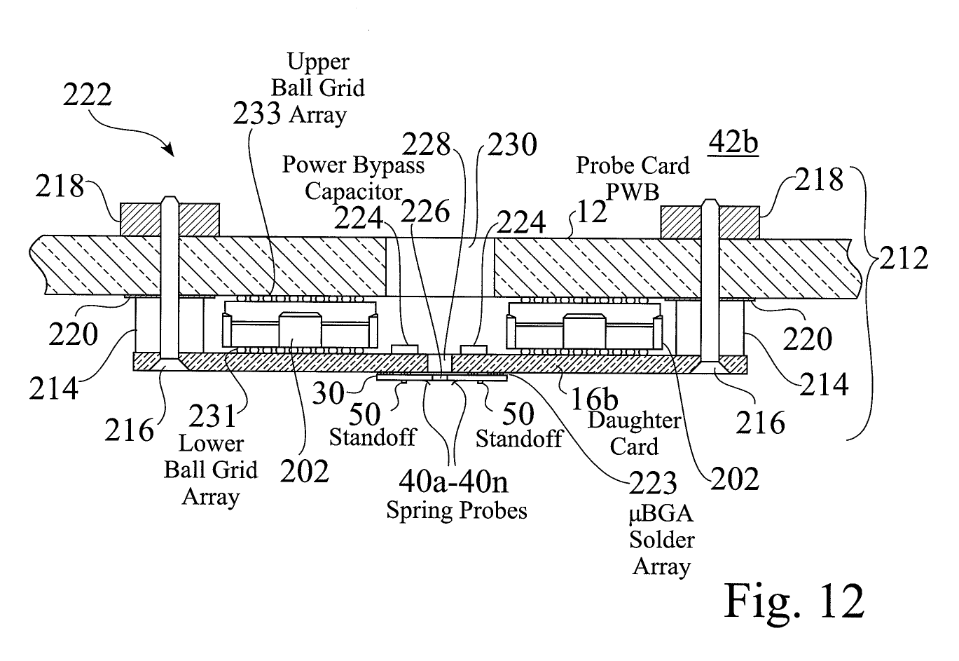

FIG. 12 is a cross-sectional view 222 of a small test area probe card assembly 42b, having one or more area separable connectors 202, e.g. array connectors 202 located between the mother board 12 and a daughter card 16b, which is attached to a small area spring probe substrate 30.

While many of the probe card assemblies 42 described herein provide large planarity compliance for a probe chip contactor substrate 30, some probe card assemblies 42 are used for applications in which the device under test comprises a relatively small surface area. For example, for applications in which a small number, e.g. one to four, of integrated circuits 26 are to be tested at a time, the size of a mating substrate 30 can also be relatively small, e.g. such as less than 2 cm square.

In such embodiments, therefore, the planarity of the substrate 30 to the wafer under test 20 may become less critical than for large surface areas, and the compliance provided by the probe springs 40a-40n alone is often sufficient to compensate for the testing environment. While the compliance provided by the probe springs 40a-40n may be relatively small, as compared to conventional needle springs, such applications are well suited for a probe card assembly 42 having photolithographically formed or MEMS formed spring probes 40a-40n.

The probe card assembly 42b is therefore inherently less complex, and typically more affordable, than multi-layer probe card assembly designs. The small size of the substrate 30 reduces the cost of the probe card assembly 42b, since the cost of a probe chip contactor assembly 18 is strongly related to the surface area of the probe chip substrate 30.

The probe springs 40a-40n are fabricated on the lower surface 48a of a hard probe chip substrate 30, using either thin-film or MEMS processing methods, as described above. Signals from the probe springs 40a-40n are fanned out to an array of metal pads 64 (FIG. 2), located on the upper surface 48b of the substrate 30, using metal traces 34a,34b on one or both surfaces 48a,48b, and conductive vias 66a-66n through the substrate 30. The top side pads 64 are connected to a daughter card 16b, using common micro-ball grid solder array pads 223, typically at an array pitch such as 0.5 mm. The daughter card 16b further expands the pitch of the array, to pads 231 having an approximate pitch of 0.050 inch on the opposing surface of the daughter card 16b. One or more area array connectors 202, such as MEG-Array® connectors, from FCI Electronics Inc. of Etters, Pa., are used to connect the 0.050 inch pitch pad array 231 to an upper ball grid array 233 on the mother board 12. Power bypass capacitors 224, such as LICA® capacitors from AVX Corporation of Myrtle Beach S.C., are preferably mounted to the daughter card 16b, close to the substrate micro-BGA pads 231, to provide low impedance power filtering.

The small test area probe card assembly 42b preferably includes a means for providing a mechanical connection 212 between the mother board 12 and the daughter card 16b. In the probe card assembly 42b embodiment shown in FIG. 12, one or more spacers 214 and spacing shims 220 provide a controlled separation distance and planarity between the daughter card 16b and the mother board 12, while one or more fasteners 216 and nuts 218 provide means for mechanical attachment 212. While a combination of spacers 214, shims 220, fasteners 216, and nuts 218 are shown in FIG. 12, alternate embodiments of the small test area probe card assembly 42b may use any combination of means for attachment 212 between the daughter card 16b and the mother board 12, such as but not limited to spring loaded fasteners, adhesive standoffs, or other combinations of attachment hardware. In some preferred embodiments of the small test area probe card assembly 42b, the mechanical connection 212 between the mother board 12 and the daughter card 16b is an adjustable mechanical connection 212, such as to provide for planarity adjustment between the mother board 12 and the daughter card 16b.

Lower substrate standoffs 50, which are typically taller than other features on the probe chip substrate 30 (except for the spring tips 40a-40n), are preferably placed on the lower surface 48a of the substrate 30, preferably to coincide with saw streets on a semiconductor wafer 20 (FIG. 1) under test, thereby preventing the wafer under test 20 from crashing into the substrate 30, and preventing damage to active regions on the semiconductor wafer 20.

As shown in FIG. 12, the probe chip contactor substrate 30 may preferably include an access window 226, while the daughter card 16b also preferably includes a daughter card access hole 228, and the mother board 12 preferably includes an access hole 230, such that access to a semiconductor wafer 20 is provided while the probe card assembly 42b is positioned over the wafer 20, e.g. such as for visual alignment or for electron beam probing. Access holes 226, 228, 230 may preferably be used in any of the probe card assemblies 42.

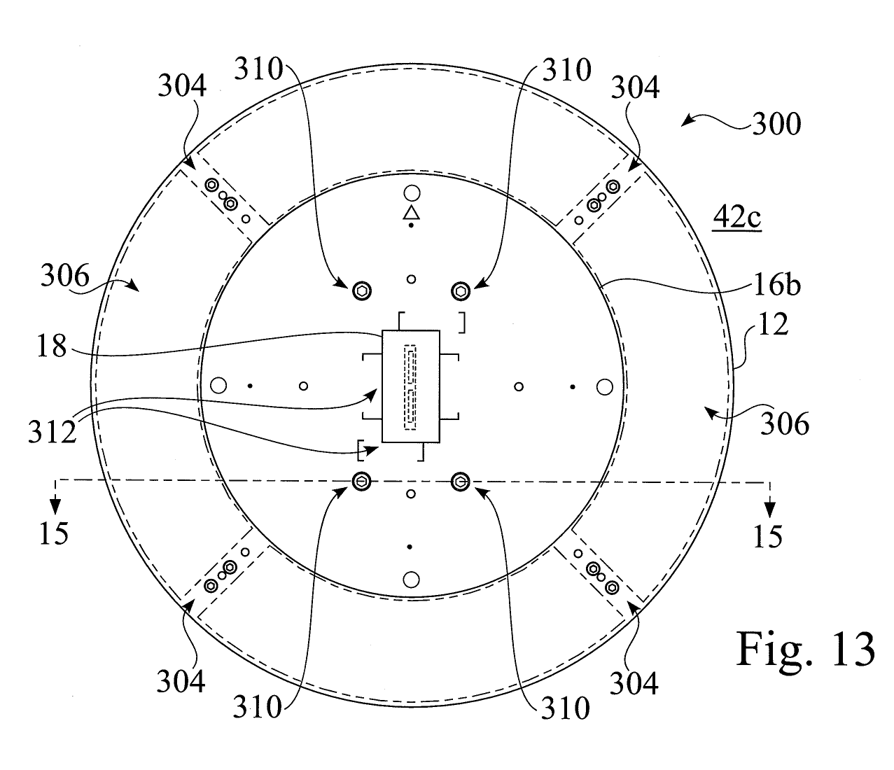

Improved Probe Card Assemblies. The use of separable connectors 202 can be used in a wide variety of enhanced probe card assemblies, such as in conjunction with enhanced stiffeners 38 and/or enhanced attachment means 310 (FIGS. 13-17) between the motherboard 12 and a central structure 16, e.g. daughter card 16b.

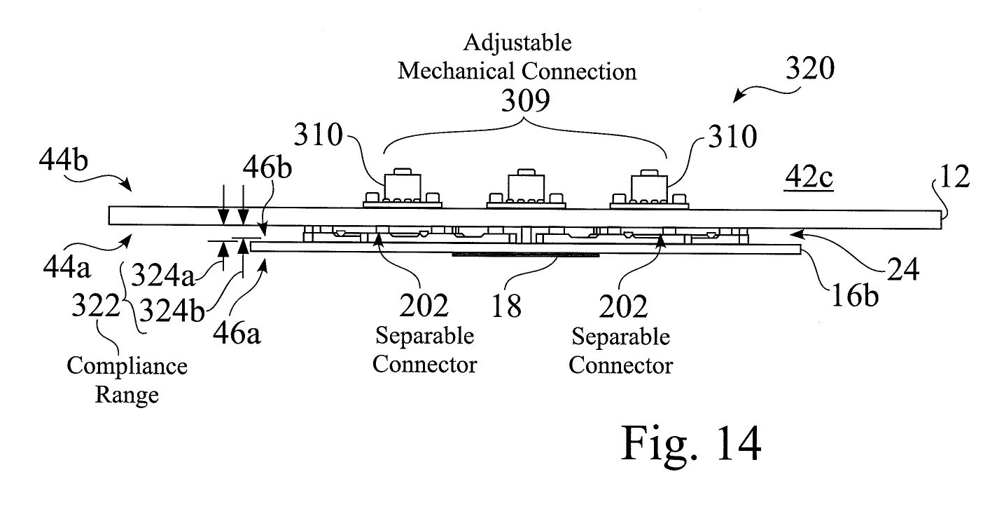

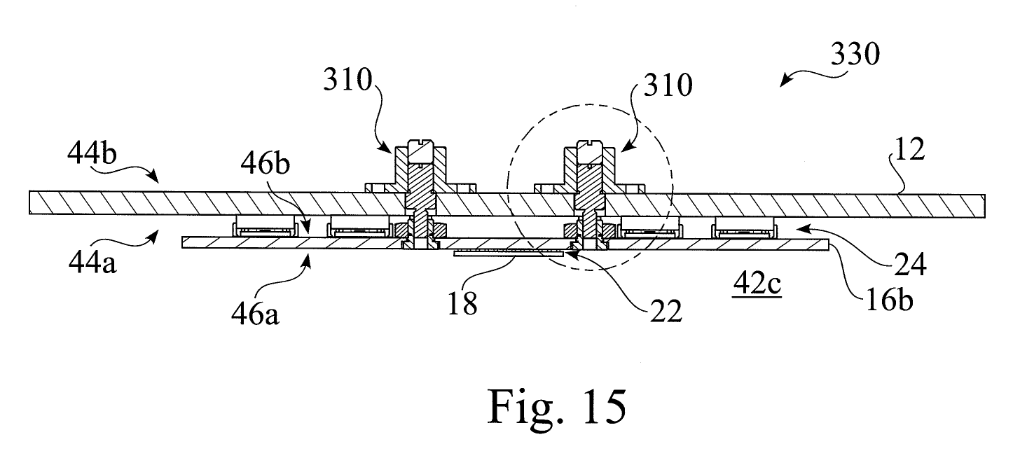

FIG. 13 is a lower, i.e. probe side, plan view 300 of an LCD platform structure for a probe card assembly 42c. FIG. 14 is a side view 320 of an LCD platform structure for a probe card assembly 42c. FIG. 15 is a cross sectional side view 330 of an LCD platform structure for a probe card assembly 42c.

In the exemplary probe card assembly 42c seen in FIG. 13, a cingulated probe chip contactor assembly 18 is mounted to a daughter card 16b, wherein the daughter card 16b is mechanically connected 309 (FIG. 14) to the motherboard 12, such as by a plurality of actuators 310, e.g. four actuators 310. The actuators 310 typically comprise mounting and/or leveling hardware that may preferably be captive in the daughter card 16b.

The exemplary motherboard 12 seen in FIG. 13 is typically tester specific in configuration. In the motherboard 12 seen in FIG. 13, test contact regions 306 are typically defined, i.e. specified, for electrical contacts, e.g. test head pogo arrays, that are connectable to a test head structure 55 (FIG. 1). As well, a plurality of keep-out zones 304 may also be defined for all mechanical and electrical components, such as to be reserved for attachment to a test prober structure 55.

As also seen in FIG. 13, one or more keep-out areas 312 comprise one or more, e.g. four, defined areas for mechanical attachment of one or more probe chip contactor assemblies 18.

As seen in FIG. 14 and FIG. 15, the central structure 16 located between the probe chip contactor assembly 18 and the motherboard 12 preferably comprises a daughter card 16b. The exemplary lower interface 22 between the probe chip contactor assembly 18 and the daughter card 16b shown in FIG. 14 and FIG. 15 typically comprises solder connections 112, such as seen in FIG. 4.

The upper electrical interface 24 between the daughter card 16b and the mother board 12 shown in FIG. 14 and FIG. 15 typically comprises separable connectors 202. As well, the LCD platform probe card structure 42c shown in FIG. 14 and FIG. 15 comprises an adjustable mechanical connection 309, which may comprise a plurality of actuators 310, e.g. push-pull actuators 310. The actuators 310 are preferably adjustable throughout the height range of the separable connectors 202, to provide control over separation distance and planarity between the probe chip contactor assembly 18 and the mother board 12. The actuators 310 typically comprise differential screw drives, to slidably control the separable connectors 202 through their full compliance range 322, i.e. from first engagement 324a to full engagement 324b.

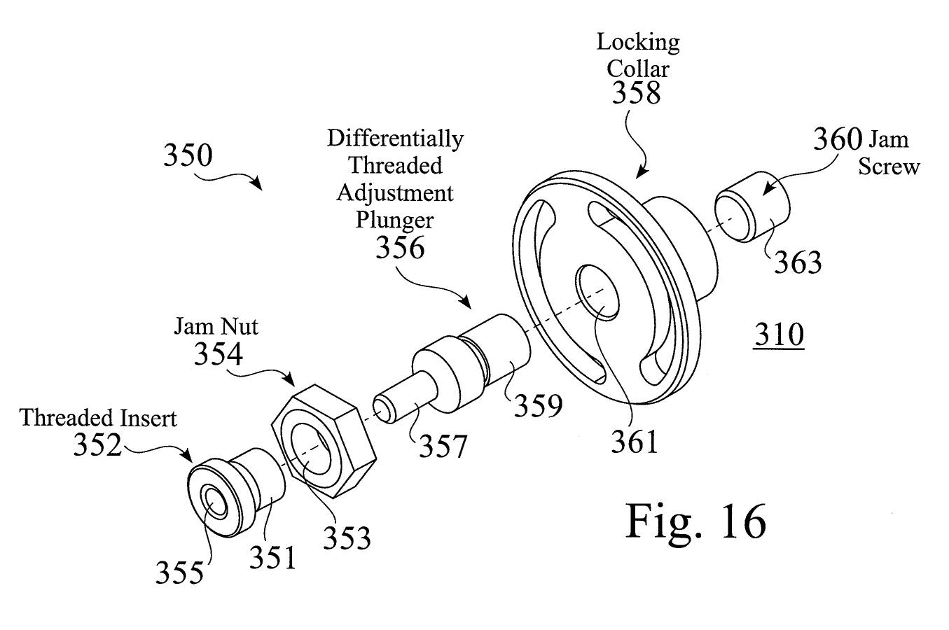

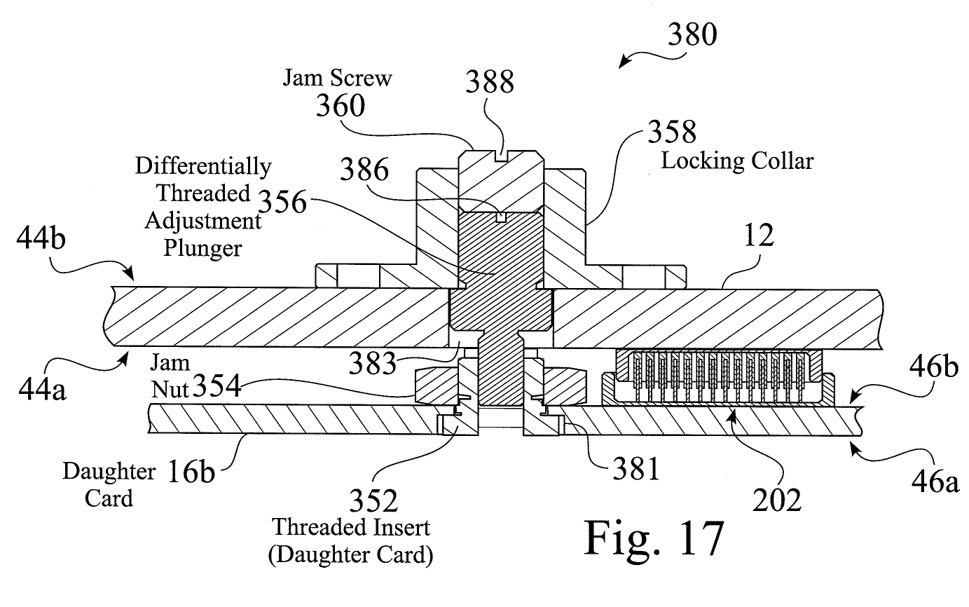

FIG. 16 is an expanded assembly view 350 of push-pull activator 310 for an LCD platform structure 42c. FIG. 17 is a detailed cutaway view 380 of push-pull activator 310 for an LCD platform structure 42c. The exemplary actuator 310 shown comprises a threaded insert 352 and a jam nut 354 that are threadably engageable 351,353 to attach to the central structure 16, e.g. a daughter card 16b. A differentially threaded adjustment plunger 356 is slidably locatable within holes 383 (FIG. 17) defined through the motherboard 12, and is threadably engageable 355,357 with the threaded insert 352. A locking collar 358 is locatable on the back surface 44b of the motherboard 12, and threadably engageable 359,361 with the differentially threaded adjustment plunger 356. The push-pull activator 310 may preferably comprise a jam screw 360, which is threadably engageable 361,363 with the locking collar 358, to lock in the current vertical position of the differentially threaded adjustment plunger 356. As seen in FIG. 17, the differentially threaded adjustment plunger 356 typically comprises means for adjustment 386, e.g. means for accepting a tool, such as a screwdriver or socket driver. The jam screw 360 seen in FIG. 17 also further comprises means for adjustment 388, e.g. means for accepting a tool, such as a screwdriver or socket driver.

Some embodiments of the LCD platform probe card structure 42c typically comprise a three or four push-pull actuators 310 that are adjustably settable throughout the height range of the separable connectors 202, to provide control over the separation distance and planarity between the central structure 16, e.g. a daughter card 16b, and the mother board 12. The push-pull actuators 310 allow the separable connectors to be slidably controllable through their full compliance range 322.

As well, one or more of the actuators may be set, such as after adjustment of any of separation distance and planarity, to provide planarity adjustment of the assembly 42c, by deflecting the probe chip contactor assembly 42. For example, adjustment of the probe card structure 42c may comprise the steps of:
adjustably setting each of the plurality of mechanical connectors 310 for any of separation distance and planarity between the daughter board 16b and the motherboard 12; and
subsequently setting at least one of the plurality of mechanical connectors 310 to provide subsequent planarity adjustment, by deflecting the probe chip contactor 18, e.g. such as by allowing bowing of the daughter card 16b at one or more points, to improve the overall planarity of the assembly 42c in relation to a wafer 20.

For some embodiments of lower probe card interface assemblies 43 (FIG. 1) that comprise probe card contactor assemblies 18 that are soldered 112 to daughter cards 16b, there can be a mismatch of thermal coefficients of expansion (TCE) between the daughter card 16b, such as comprising a printed circuit board, and a probe chip substrate 30, such as comprising ceramic 30. For some probe card assembly designs 42, a TCE mismatch can result in a bowing of the daughter card 16b, such as after soldering to the probe chip contactor assembly 18.

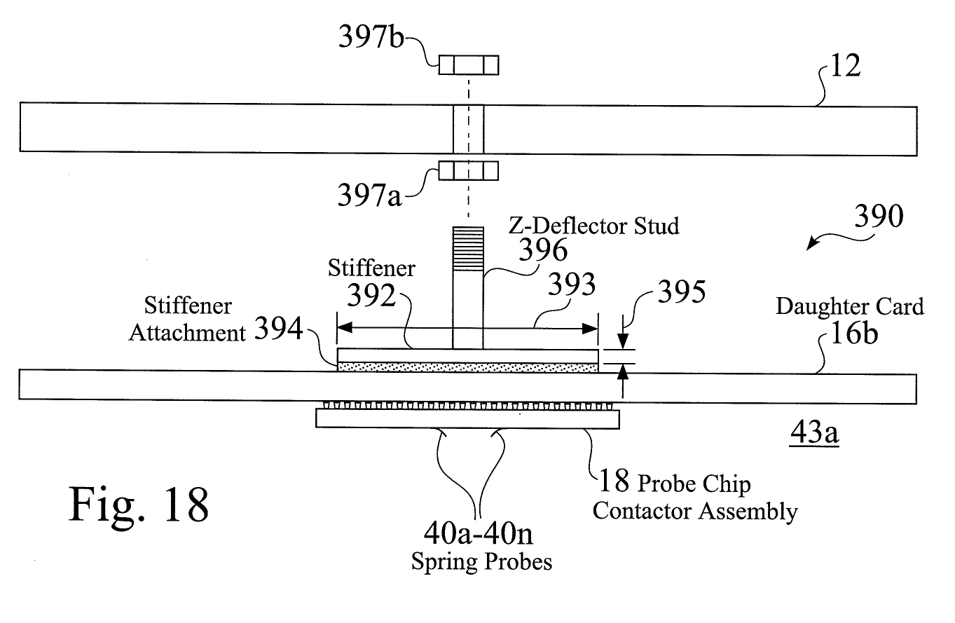

FIG. 18 is a schematic view of a probe chip contactor interface assembly 43a, comprising a daughter card 16b attached to a probe chip contactor assembly 18, and further comprising stiffening means 392 that is attached 394 to the second, i.e. back surface 46b of the daughter card 16b, to reduce thermal expansion mismatch between the daughter card 16b and the probe chip contactor assembly 18, and/or to provide increased the strength of the daughter card 16b, to resist bowing after the solder process 112, and/or during temperature cycling during use, such as at hot or cold probing temperatures.

In some embodiments of the enhanced lower probe card interface assembly 43a, the stiffener comprises any of ceramic and metal, e.g. titanium (Ti) or equivalent. The size, shape, composition, mounting structure 394 (e.g. adhesive, solder or mechanical bond), and mounting location of the stiffener 392 may preferably be optimized to compensate for bow and/or other source of non-planarity of the probe tips 40. For example the lateral dimensions 393 or thickness 395 may be chosen to impart specified mechanical or thermal characteristics for the enhanced lower probe card interface assembly 43a.

In one exemplary embodiment, a stiffener 392 is attached to the daughter card 16b and is cured at solder temperature, such as to ensure that when the daughter card 16b is heated for probe chip soldering 112, the solder bonding surface will be substantially flat. Any of the size, shape, and material of the stiffener 392 may preferably be adjusted to approximately compensate for bow due to probe chip TCE mismatch. An optional mechanical adjustment 396, 397, such as a threaded post 396 adhesively attached to the stiffener 392 and adjustable in relation to another component, e.g. the mother board 12, may preferably be used to make fine correction, e.g. applying vertical tension or compression to the daughter card 16b, such as to ensure that bow is compensated to within acceptable specifications.

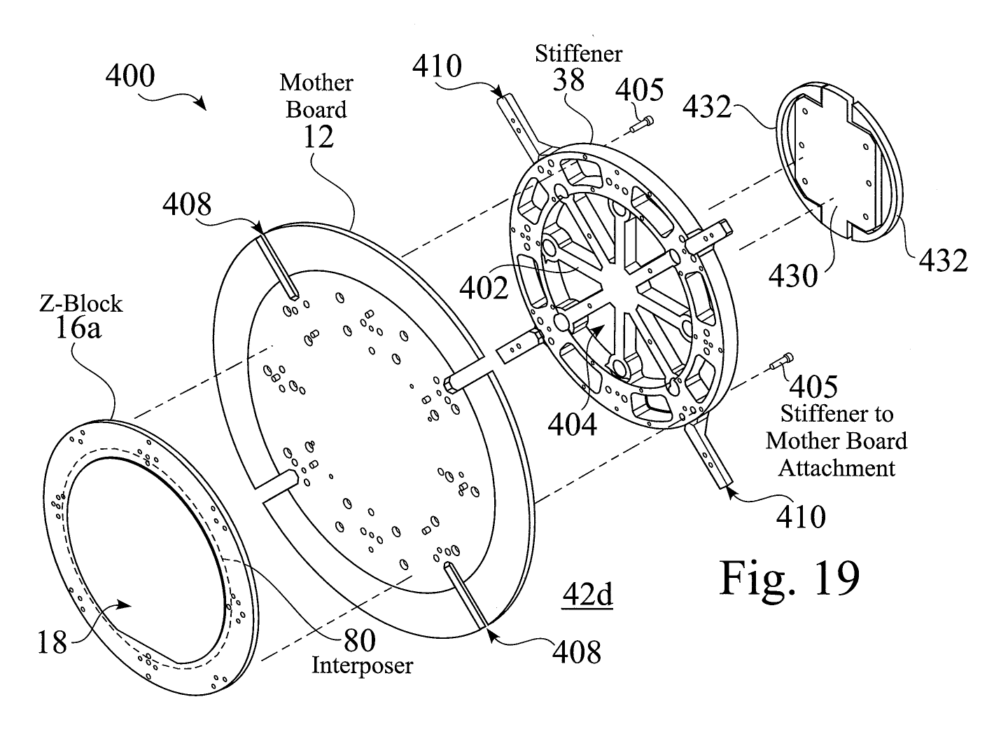

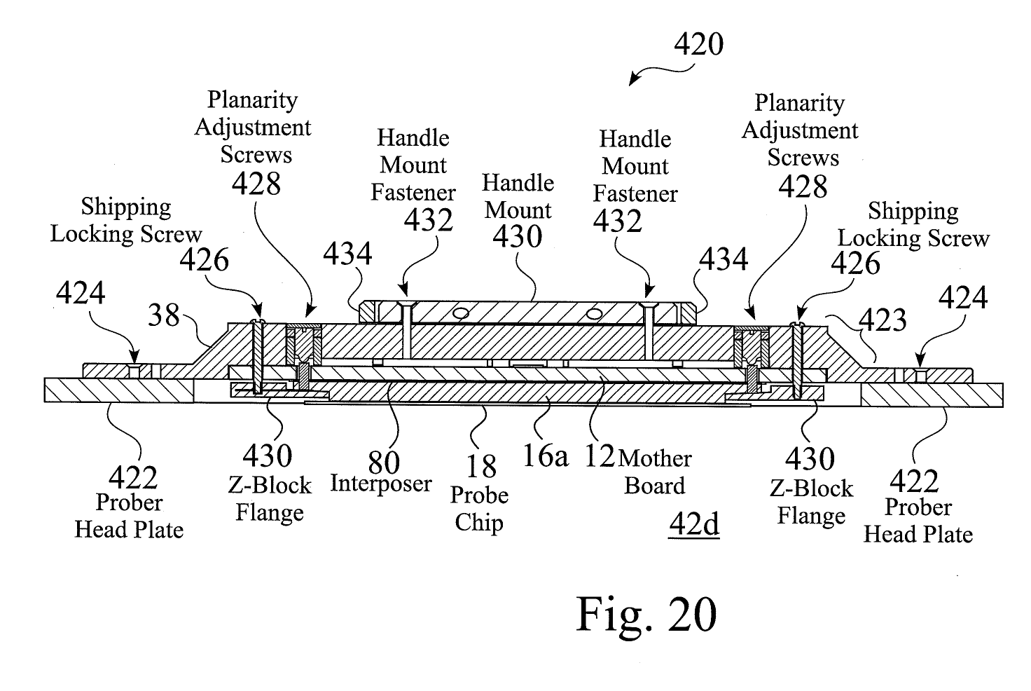

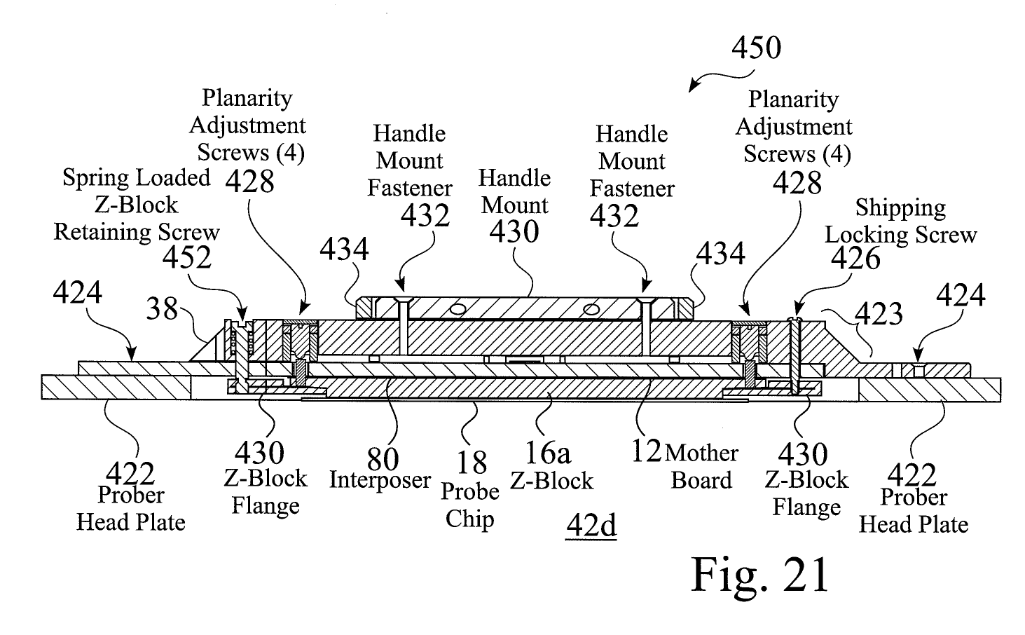

Probe Card Assemblies Having Thermal Stiffeners. FIG. 19 is a partial expanded assembly view 400 of a probe card assembly 42d having a thermal stiffener structure 38. FIG. 20 is a partial cutaway view 420 of a probe card assembly 42d having a thermal stiffener structure 38. FIG. 21 is an alternate partial cutaway view 450 of a probe assembly 42d having a thermal stiffener structure 38.

An exemplary embodiment of the probe card assembly 42d may typically comprise:
a motherboard substrate 12 having a bottom surface and a top surface, and defining a central region and an outer region extending from the central region, and a plurality of electrical conductors extending from the bottom surface to the top surface;
an interposer 80 comprising an interposer substrate 82 having an upper surface 102b and a lower surface 102a opposite the upper surface102b, a plurality of spring contacts 86 on the lower surface 102a, a plurality of electrical contacts (e.g. 92,86) on the upper surface 102b, and a plurality of electrically conductive connections 84 between the plurality of spring contacts 86 and the plurality of electrical contacts;
a probe chip 18 comprising a probe chip substrate having a probe surface 48a and a connector surface48b, a plurality of probe springs 40 on the probe surface 48a, a plurality of electrical contacts 64 on the connector surface 48b, and a plurality of probe chip electrical connections 66, wherein each of the probe springs 40 is electrically connected to at least one contact 64 through at least one probe chip electrical connection 66;
a central structure 16 comprising a Z-block substrate 16a located between the interposer substrate 80 and the probe chip substrate 18, the central structure further comprising electrical connections (e.g. 112, 122 (FIG. 4), 934 (FIG. 31), 936 (FIG. 31)) between each of the plurality of electrical contacts 64 on the probe chip substrate and each of the spring contacts 86 on the bottom surface 102a of the interposer substrate 82;
a stiffener 38 having a front surface and a back surface fixedly attachable, i.e. mountable, to the prober headplate 422 (FIG. 19; FIG. 20, the front surface in contact with at least a portion of the top surface 44b of the motherboard substrate 12;
and a plurality of mechanical connections between the stiffener 38 and the central structure 16, surrounding the interposer and within a central region of the motherboard substrate 12, wherein the mechanical connections are configured to allow the motherboard to expand and contract vertically 27 and radically 23,25 with respect to the stiffener 38, thereby decoupling radial and/or vertical thermal expansion and contraction of the motherboard, and thermally stabilizing the orientation of the probe chip substrate 30 relative to the stiffener mounting surface over a predetermined operating temperature range, e.g. transmitting only minimal changes in orientation of the probe chip substrate 30 relative to the stiffener mounting surface, and/or the prober head plate 422, over a wide range of operating temperatures.

The stiffener 38 for the probe card assembly 42d preferably comprises a material having a low thermal expansion coefficient, e.g. less than 6×10⁻⁶/° C. @20-50° C., such as but not limited to Nobinite, mehanite, or Invar, to reduce soak time, i.e. pre-warming of a probe card assembly prior to use, and/or to increase thermal stability of attached mother board 12. For example, in some embodiments of the probe card assembly 42d, the stiffener 38 comprises nobinite cast iron, available through Enomoto USA, of Torrance Calif. Nobinite thermal stiffeners 38 have a thermal coefficient of expansion (TCE) that is significantly less than that of carbon steel, over a wide temperature range. For example, different Nobinite alloys typically comprise a TCE from about 0 to 5×10⁻⁶/° C. @20-50° C., as compared to 11 to 12×10⁻⁶/° C. @20-50° C. As well some varieties of Invar have a TCE of about 0 to 1×10⁻⁶/° C. @20-50° C. The exemplary mother board 12 seen in FIG. 18 incorporates four machined in bosses 403 defined therein, to receive stiffener mounting bosses 410 therein, and to provide a plane for the probe card assembly 42d to rest against the wafer handler, i.e. prober head plate 422, wherein the mother board (PCB) 12 can expand and contract thermally, while minimizing probe tip movement.

The Z-block 16a in FIG. 20 and FIG. 21 is retained by a Z-bock Flange 430, which is attached to the motherboard 12, such as by a plurality of spring-loaded Z-block retaining screws 452. An Interposer 80 is located between the Z-Block 16a and the motherboard 12, to provide a compliant interface for electrical connections. Pins 935 (FIG. 31) may be used to align the interposer 80 to the motherboard 12.

Planarity of the Z-block 16a is provided by a plurality of adjustment screws 428. A plurality of locking screws 426 between the Z-bock flange 430 and the motherboard 12 are also typically included for shipping and/or storage, such as to be removed during installation.

Some embodiments of the probe card assembly 42d have a reduced number of attachment points between the Z-block flange 430 and the mother board 12, to allow the motherboard PCB 12 to float in relation to the Z-block 16a and probe chip contactor assembly 18. While the motherboard may comprise a material having a thermal coefficient of expansion (TCE) more than that of the stiffener, the points of connection between the motherboard 12 and the stiffener 38 may preferably be located toward a central region, such that the motherboard 12 may expand and contract over a range of temperatures, without significant warping.

As seen in FIG. 19, the central region of the stiffener 38 typically comprises planar supports 402 across portions of the central region of the motherboard 12, as well as a plurality of hollow regions 404, such as to provide connection regions and/or regions for the attachment of componentry on the back side 44b of the mother board 12. As also seen in FIG. 20 and FIG. 21, the stiffener 38 may preferably have a dished cross section 423, to provide increased structural integrity across the central region.

The design and materials chosen for the probe card assembly 42d therefore provide enhanced planar support for the mother board 12, which typically comprises a PC board. The probe card assembly 42d allows the mother board 12 to swell and shrink, while keeping the probe chip contactor assembly the same in planarity, despite temperature fluctuation.

Plated Interposer Structure and Process. Interposers that have many contacts in parallel are sometimes subject to contamination from particulates or other contamination layers that may cause the electrical contact to be unreliable under use conditions, such as including repeated mechanical and thermal cycling.

A controlled increase of interposer contact force is associated with an increase in the reliability of the electrical contacts under use conditions, as well as during aging and storage in environments in which surface films can form. While it is desirable to increase the contact force, it is undesirable to increase contact force excessively, since the force to compress the interposer becomes too high, which may cause unacceptable mechanical deflection of the interposer and probe card structures. It may therefore be desirable to provide interposers that provide high quality low resistance electrical connections without requiring excessive contact force.

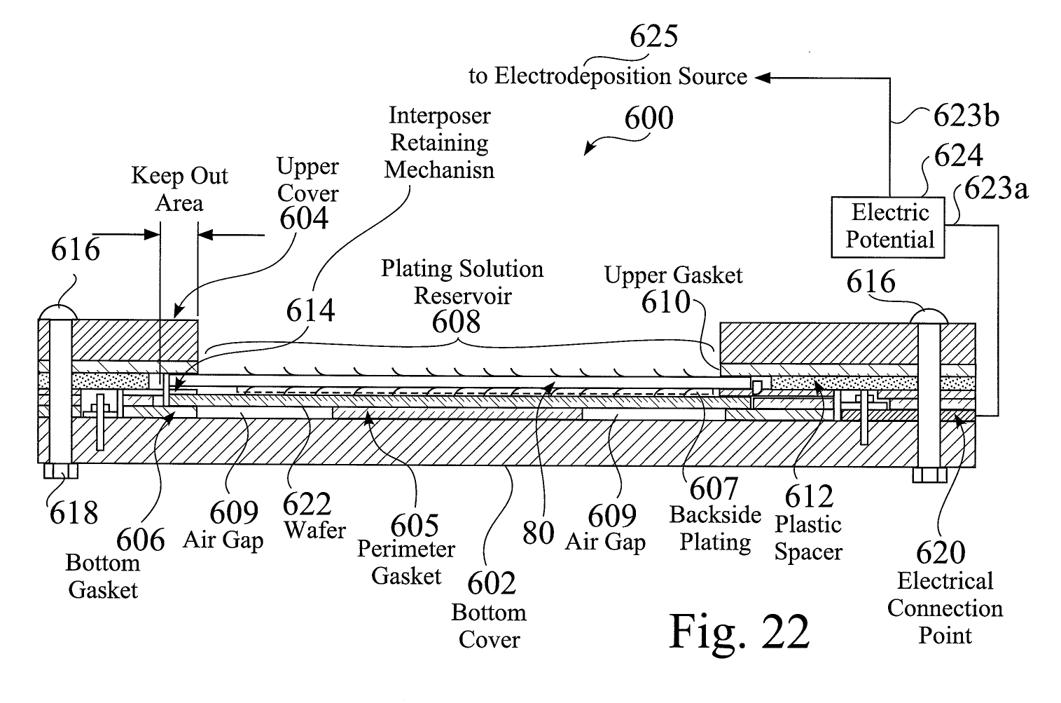

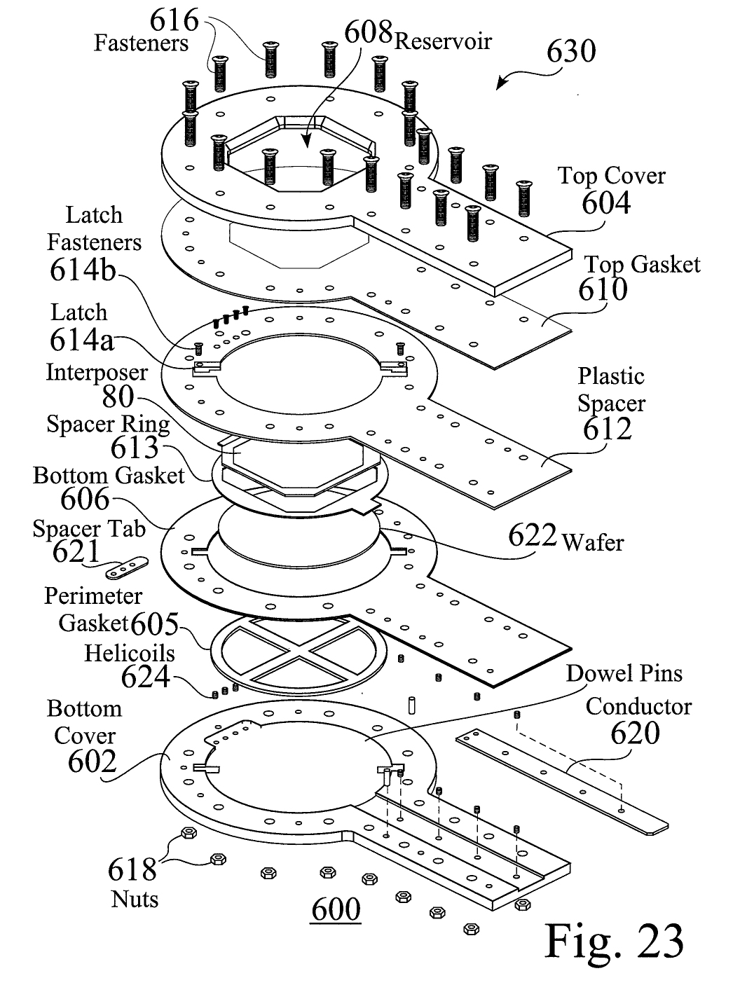

FIG. 22 is a partial cross sectional view of an interposer plating fixture 600. FIG. 23 is an expanded assembly view 630 of an exemplary interposer plating fixture 600. The interposer plating fixture 600 provides immersion of the lifted and un-plated “fingers” on a first side 102, e.g. 102a, of an interposer 80 in plating solution, while providing a liquid tight seal around the periphery of the surface of the first side 102 of the interposer wafer 82. The interposer plating fixture 600 also provides electrical contact to one or more interposer contacts to support electroplating, such as from the opposite side 102, e.g. second side 102b of the interposer 80, opposite to the first side 102, e.g. 102a, of the interposer 80, such as through a conductor 620, through a wafer 620, and through the electrically conducting through-vias 84 associated with each of the lifted fingers 86 on the first and second sides of the interposer 80.

The exemplary interposer plating fixture 600 seen in FIG. 22 and FIG. 23 comprises a bottom cover 602 that is mated to a top cover 604, to confine an interposer work piece 80, to provide a plating solution reservoir 608 for which one side 102, e.g. 102a of a captive interposer 80 is submerged, and to provide an electrical connection 620 to the opposing side 122 of the interposer work piece 80. The exemplary interposer plating fixture 600 seen in FIG. 22 and FIG. 23 comprises a bottom cover 602, top cover 604, a bottom gasket 606, a perimeter gasket 605 supporting a conductive wafer 622, a plating solution reservoir 608 defined between a captive interposer and the lower cover, a plastic spacer 612, e.g. surrounding and extending from the interposer 80, a top gasket 610, an interposer retaining mechanism 614, e.g. such as comprising interposer latches 614a and latch fasteners 614b, fixture assembly screws 616 and nuts 618, means for electrical connection 620, e.g. a conductor strip 620, a wafer 622, and helicoils 624 as needed. In some embodiments, the wafer 622 comprises a flexible or pliable member, e.g. silicon, having a conductive layer on one or both sides, to provide a complaint electrically conductive pathway to the side 102 of the interposer opposite the reservoir 208.

The lifted fingers 86 on the first side 102a and second side 102b of the interposer 80 typically comprise stress metal springs, e.g. having a similar construction to contactor spring probes 40, comprising MoCr or equivalent materials, optionally over coated 94 with a conductive material, e.g. Au, Rh, etc., to provide low contact resistance to a planar surface, e.g. a Ti—Au coated wafer 82, e.g. comprising ceramic or silicon).

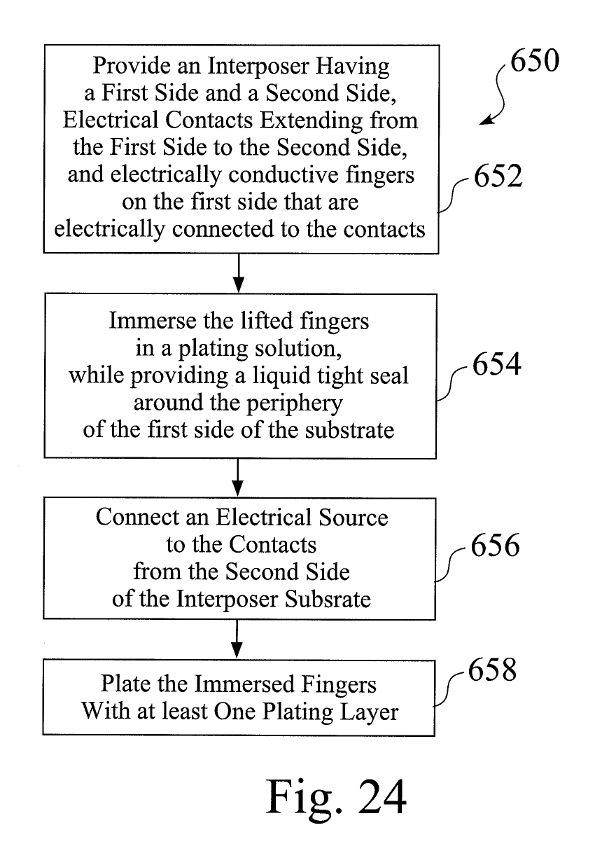

FIG. 24 shows an exemplary interposer plating process 650, wherein lifted spring probes 86 extending from at least one side 102 are plated, such as within a plating structure 600. The exemplary process comprises the steps of:
providing 652 an interposer 80 having a first side 102a and a second side 102b, electrical contacts, e.g. vias 84, extending from the first side 102a to the second side 102b, and electrically conductive fingers 86 on the first side that are electrically connected to the contacts 84;
immersing 654 the lifted fingers 84 in a plating solution 608 (FIG. 22), while providing a liquid tight seal around the first side 102a of the substrate 82;
connecting 656 an electrical source, e.g. 624 (FIG. 22), to the contacts 84 from the second side 102b of the interposer substrate 82 (e.g. such as by using backside plating 607 (FIG. 22); and
plating 658 the immersed fingers 86 with at least one plating layer.

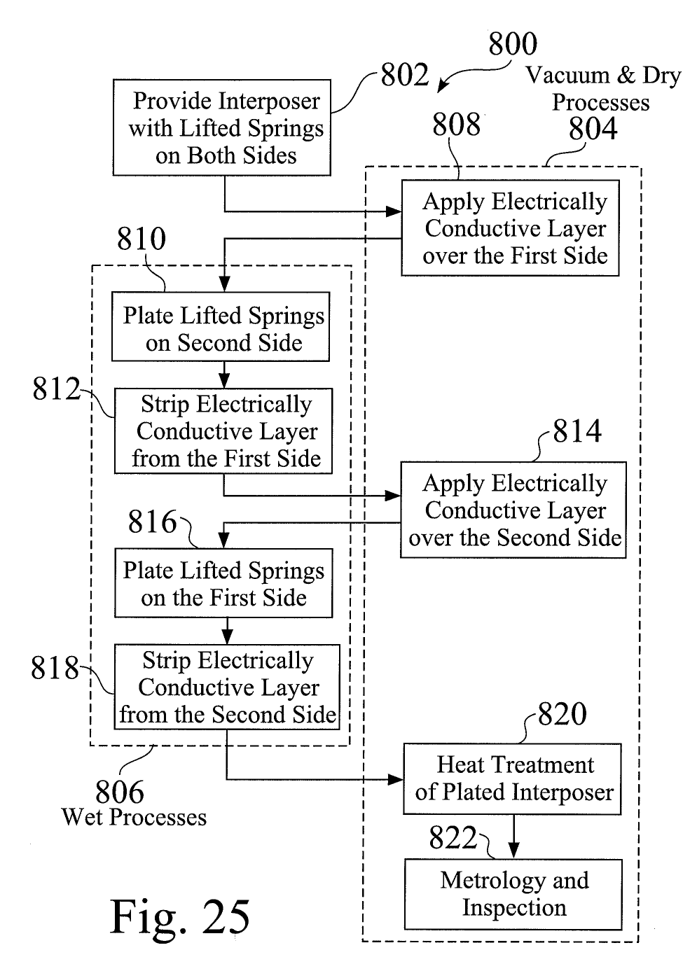

FIG. 25 is an expanded process flow diagram for an interposer plating process 800, which comprises the steps of:
providing 802 an interposer 80 with lifted springs 86 on both sides 102a,102b;
applying 808, e.g. such as by sputtering, electro or electroless plating, etc., an electrically conductive layer 607 (FIG. 22), such as copper, over the first side;
plating 810 the lifted springs on the second side with at least one outer layer;
stripping 812 the electrically conductive layer from the first side;
applying 814, e.g. such as by sputtering, electro or electroless plating, etc., an electrically conductive layer), such as copper, over the second side;
plating 816 the lifted springs on the first side with at least one outer layer;
stripping 818 the electrically conductive layer from the second side;
optionally heat treating 820 the plated interposer; and
as needed, performing 822 metrology, i.e. measurement, and/or inspection.

The sputtering steps 808 and 814 are performed to provide an electrically conductive layer 607 (FIG. 22), that is connected to a power source 624 (FIG. 22) to perform back plating of the opposing sides 102a,102b. The electrically conductive layer 607 for some embodiments of the interposer plating process 800 comprises copper (Cu) or an alloy thereof, such as having a thickness of approximately 0.01 um to 1 um.

The plating steps 810 and 816 typically comprise the plating of one or more outer layers 892a-892g, such as to provide desirable performance characteristics for the springs 86, and/or to provide enhanced bonding for subsequent outer layers. For example, in a current exemplary embodiment:
a first outer layer 892 comprises nickel, having a thickness of about 0.1 um-5 um (e.g. 5 um), such as chosen to provide adequate spring force to produce reliable contacts (while the total interposer compression force is preferably minimized to reduce mechanical deflection of the probe card mother board 12); and
a second outer layer 894 plated over the first outer layer 892 comprises gold (Au), having a thickness of about 0.1 um-5 um (e.g. 0.5 um), such as chosen to be thick enough to resist wear during cycling of the interposer 80.

For example, one or more of the outer plating layers 892 may preferably increase the spring rate for the interposer springs from about 0.1 g/mil to between about 0.05 g/mil to about 1 g/mil, e.g. with about 1 um to about 10 um microns Ni or between about 3 um to 6 um Ni). As well, the an probing contact layer 894 may be applied, such as comprising about 0.5 um to about 3 um, e.g. optionally either hard Au, Rh, or PdCo.

The stripping steps 812 and 818 are performed to remove the temporary plating player from the opposing side, e.g. 102a or 102b, of the interposer 80, such as by using a stripping agent comprising sodium persulfate (Na₂S₂O₃).

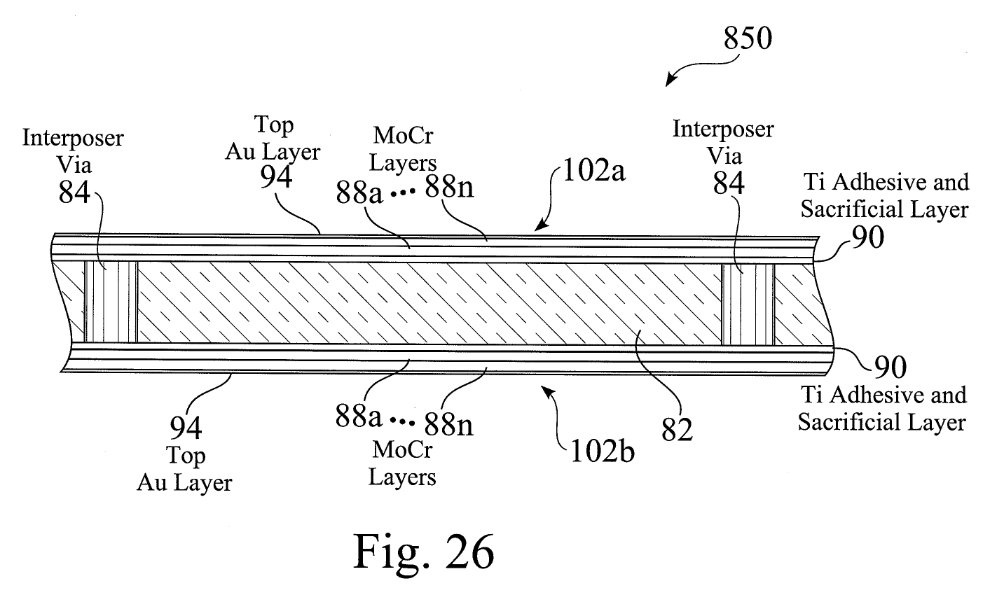

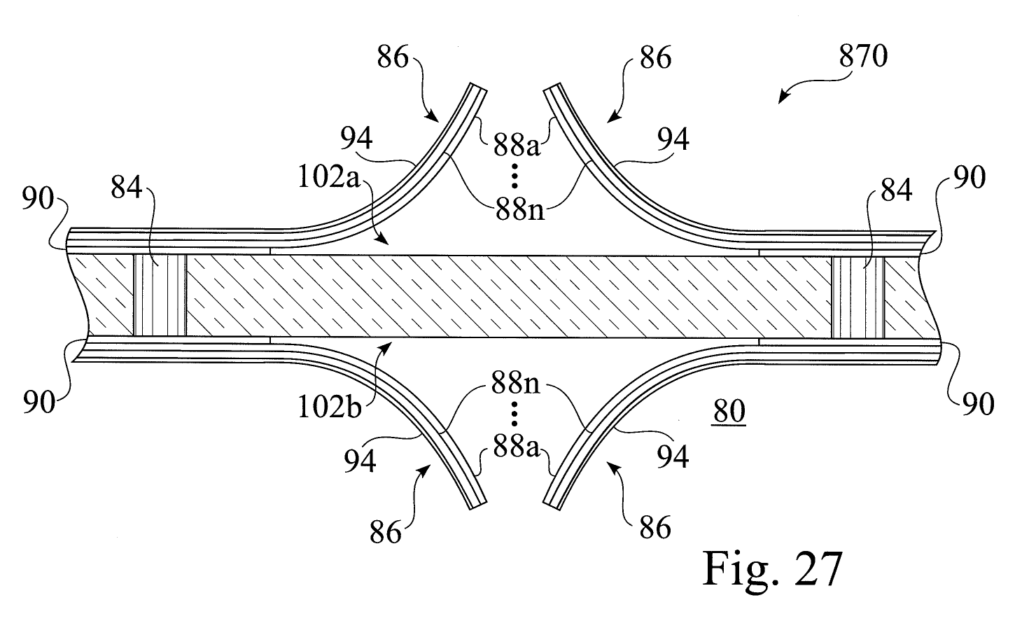

FIG. 26 shows a partial cutaway view 850 of an interposer structural element after photolithography and before lifting, such as comprising a substrate 82 having opposing sides 102a and 102b, and interposer vias 84 extending there through. As described above, each layer of the exemplary interposer substrate 82 is typically plated with an adhesive, i.e. release layer 90, and one or more spring layers 88, e.g. 88a-88n. As well, at least one top layer 94, such as comprising gold, may be plated on top of the spring layers 88 before lifting. FIG. 27 shows a partial cutaway view 870 of an interposer structural element after lifting of spring elements 86, wherein the lifting of the spring elements 86 may preferably be similar to the processes associated with the formation of spring probes 40.

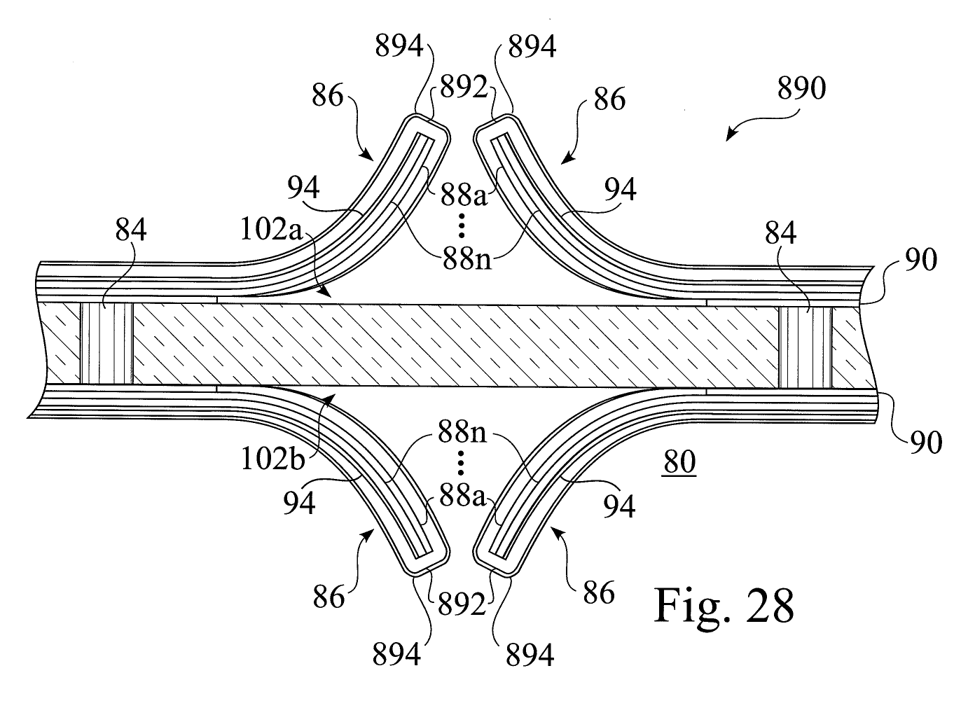

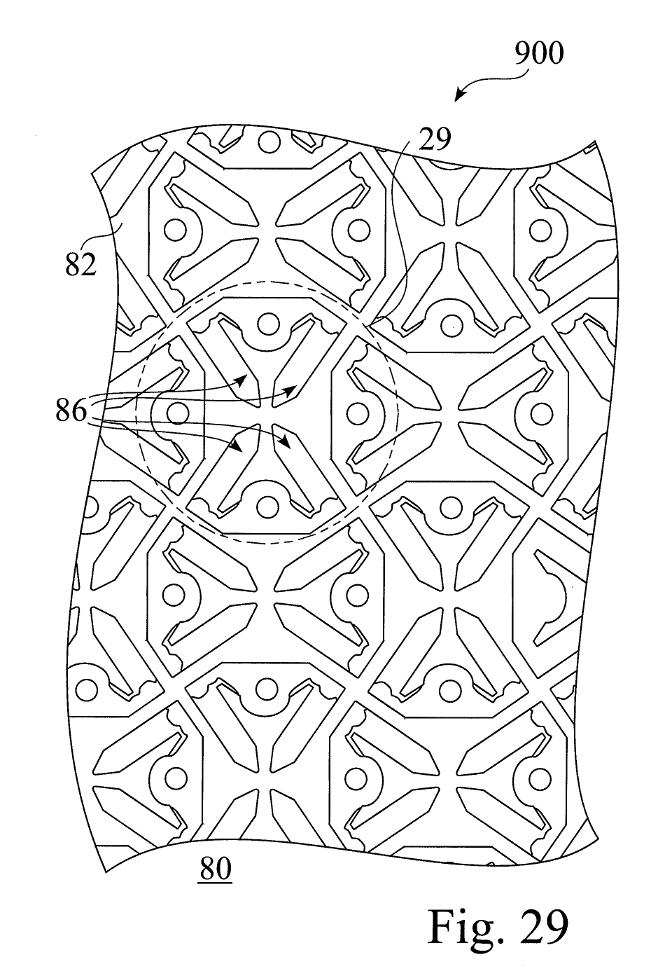

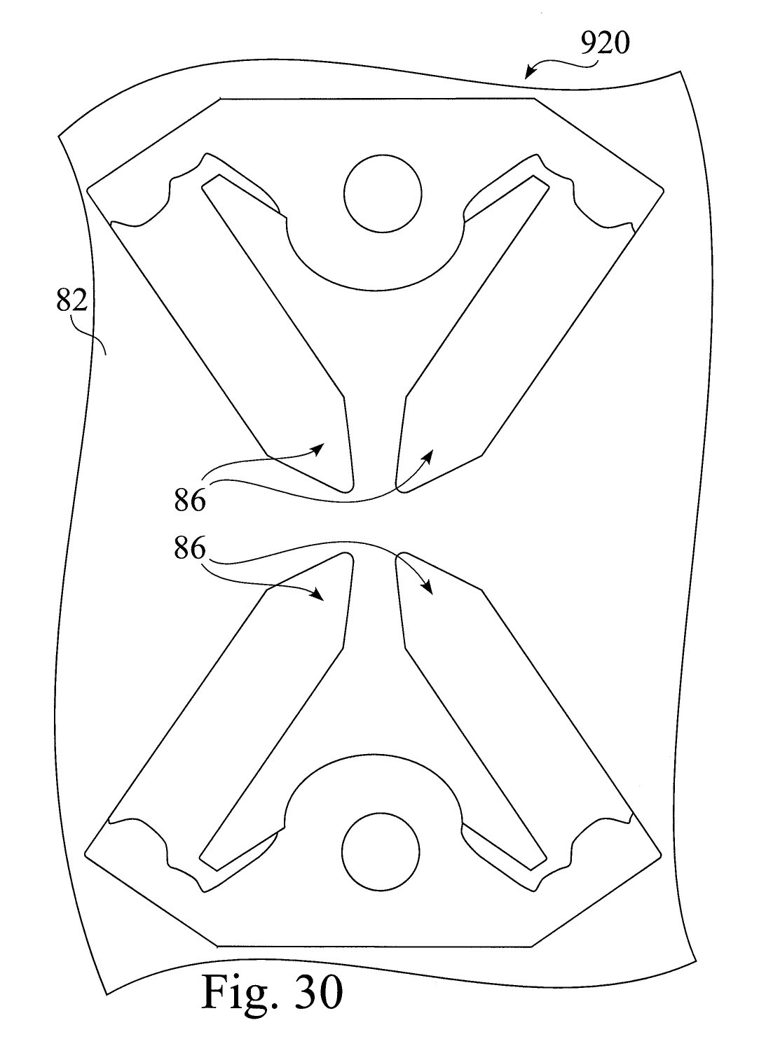

FIG. 28 shows a partial cutaway view 890 of an interposer structural element 80 after plating 892,894 of lifted spring elements 86. FIG. 29 shows a partial plan view 900 of an interposer structural element 80 after plating 892,894 of lifted spring elements 86. FIG. 30 shows a detailed partial plan view 920 of an interposer structural element after plating 892,894 of lifted spring elements.

FIG. 31 is a detailed partial schematic view 930 of a probe card system 42e comprising a soldered probe chip contactor assembly 18, and having a double-sided upper interposer 80a. FIG. 32 is a detailed partial schematic view 190 of a probe card system 42f comprising a soldered probe chip probe card embodiment having a single sided upper interposer 80b. One or more travel stops 952 are preferably included to prevent the probes 86 from damage if the upper interposer 80b is bottomed out against the probe card motherboard 12. The upper interposer 80b may be plated to increase the probe force of interposer spring probes 86.

Outer alignment pins 932 typically extend from the top stiffener 38 through the probe card assembly 42d,42e, such as through the motherboard 12 to the Z-block flange 430. The outer alignment pins 932 engage mechanical registration features 933, such as notches, slots, and/or holes, or any combination thereof, defined in components in the probe card assembly 42, e.g. 42d,42e, such as the motherboard 12 and the Z-block flange 430. The use of registration features 933 preferably allows for differences in thermal expansion between components in the probe card assembly 42, to allow testing over a wide temperature range.

While the exemplary plating processes and structures disclosed herein are described in regard to plating of interposers, it should be understood that the disclosed structures and processes can also be performed on other substrates, such as for probe chip contactor assemblies 18 having spring probes 40a-40n extending there from.

For example, an electrically conductive layer can similarly be applied to the back surface 48b of a probe chip contactor assembly 18 to provide electrical conduction for plating the spring contacts on the front side 48a, such as by any of sputtering electro or electroless plating 808 an electrically conductive layer 607 (FIG. 22), such as copper or gold over the back side 48b, connecting an electrical potential to the backside plating layer 607, and plating 810 the lifted springs 40a-40n on the probe side 48a with at least one outer layer, e.g. 892 and/or 894.

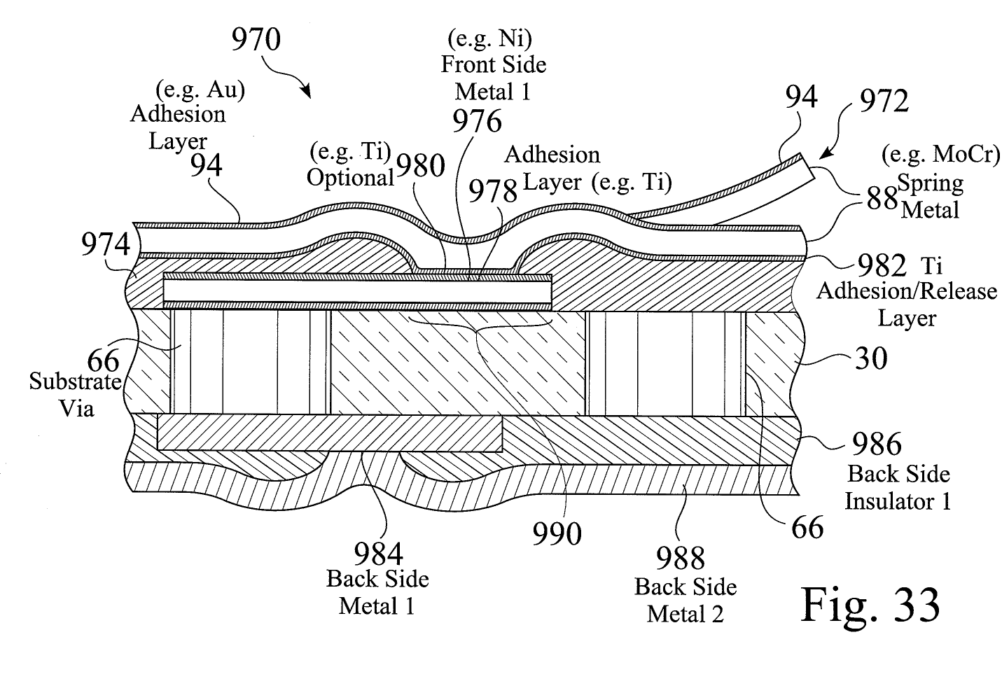

Additionally, backside plating may be performed to decrease trace resistance, while optimizing use of area of the probe chip substrate 30, such as for probing more die with a single substrate. In some embodiments, a CrCu seed layer is sputtered on the back side 48b of the probe chip contactor assembly 18. Photo resist is then deposited and patterned, such that contact is made to the base metal on the front side 48a of the probe chip contactor assembly 18, such as comprising but not limited to any of TiMoCr, TiNi and CrNi, which may preferably be selected to reduce trace resistance. Low resistance metals such as copper may also be plated on the back side interconnect layers (FIG. 33, 984,988) to reduce series resistance and improve fan-out.

Contactor Assembly Structures Having Multiple Layer Interconnections. FIG. 33 shows a cross sectional view 970 of a structure an unplated lifted spring or probe finger 972, e.g. 40,86, and associated electrically conductive routing layer 88, a front side insulating layer 974, an electrically conductive routing layer 976 having X and Y routing capability, a substrate 30 and an electrically conductive thru vias 66, a first electrically conducting routing layer 984, a back side insulating layer 986, and a second back side electrically conductive routing layer 988. In one embodiment, any of back side metal layers 984 and 988 comprise a plated metal layers composed of any of Copper, Nickel, or Gold. Both back side routing layers 984 and 988 have X and Y routing capabilities. In on embodiment, any of the front and back side insulating layers 974 and 986 comprise polyimide.

In addition, lateral stresses generated by heating, cooling and/or spring deflection are relieved by the stress decoupling layer 974. In embodiments where the stress decoupling layer 974 is formed from a polymer, e.g. polyimide, the structure is capable of withstanding spring fabrication temperature cycles, as well as most extreme temperatures encountered in the use case, e.g. −100 C to +350 C.

The disclosed decoupled spring and contactor structures provide numerous improvements, such as for providing improvement in any of fine pitch probing, cost reduction, increased reliability, and/or higher processing yields. For example, electrical contact between the spring probe structures, e.g. springs 40,86 and the substrate via structures, e.g. 66,84, is controllably defined with a formed fulcrum region 990.

Decoupled spring and contactor structures may therefore provide improved process temperature performance and adhesion margin. As well, key parameters are decoupled in decoupled spring and contactor structures, whereby design parameters may be independently optimized. As well, Decoupled spring and contactor structures may readily be modeled and tested, provide advantages in scalability.

In some embodiments of the enhanced sputtered film processing system 10 and method 150, measurement and/or compensation are provided for any of the lift height 262 and the X-Y position of photolithographically patterned spring contacts 246. For example, any of the spring length and angle may preferably be measured and/or adjusted on the photolithographic mask to compensate for any errors, e.g. dimensional or positional, measured in produced spring substrate assemblies.

While some embodiments of the structures and methods disclosed herein are implemented for the fabrication of photolithographically patterned springs, the structures and methods may alternately be used for a wide variety of connection environments, such as to provide mechanical compliance and/or electrical connections between any of contacts, connectors, and/or devices or assemblies, over a wide variety of processing and operating conditions.

Accordingly, although the invention has been described in detail with reference to a particular preferred embodiment, persons possessing ordinary skill in the art to which this invention pertains will appreciate that various modifications and enhancements may be made without departing from the spirit and scope of the claims that follow.

1. A structure, comprising:
a probe chip assembly comprising a substrate having a front surface and a back surface, and a plurality of elastic core members, each elastic core member having an anchor portion attached to the front surface of the substrate and a free portion extending away from the front surface of the substrate;
a second planar structure having a first surface and a second surface opposite the first surface;
at least one connection structure between a back surface of the probe chip assembly and the first surface of the second planar structure, wherein the connection structure comprises at least two solder regions having a first melting point and a second melting point, wherein the first melting point is lower than the second melting point;
wherein the solder region having the first melting point comprises a heatably reflowed electrically conductive region.

2. The structure of claim 1, wherein the second planar structure comprises any of a Z-Block and a daughter card.

3. The structure of claim 1, further comprising a component attached to any of the back surface of the probe chip assembly and the first surface of the second planar structure

4. The structure of claim 1, wherein the attached component comprises any of a passive component and an active component.

5. A process, comprising the steps of:
providing a probe chip assembly comprising a substrate having a front surface and a back surface, and a plurality of elastic core members, each elastic core member having an anchor portion attached to the front surface of the substrate and a free portion extending away from the front surface of the substrate:
providing a second planar structure having a first surface and a second surface opposite the first surface;
establishing at least one connection structure between a connection surface of the probe chip assembly and the first surface of the second planar structure, wherein the connection structure comprises at least two solder regions having a first melting point and a second melting point, wherein the first melting point is lower than the second melting point; and
heating the at least one connection structure to at least the first melting point.

6. The process of claim 5, wherein the second planar structure comprises any of a Z-Block and a daughter card.

7. The process of claim 5, further comprising the step of:
affixing the probe chip assembly and the second planar structure in relation to each other before the heating step;
wherein the heating step reflows the solder having the first melting point corresponding to the at least one connection, to establish a controlled gap distance between the connection surface of the probe chip assembly and the first surface of the second planar structure.

8. The process of claim 5, wherein the probe chip assembly further comprises at least on electrical component located on the connection surface.

9. The process of claim 8, wherein the at least one electrical component comprises any of a passive component and an active component.

10. The process of claim 5, wherein at least one of the solder regions comprises any of a solder ball and a solder column.

11. A process, comprising the steps of:
providing a work piece comprising
a substrate having a front surface and a back surface, and
a plurality of elastic core members, each elastic core member having an anchor portion attached to the front surface of the substrate and a free portion extending away from the front surface of the substrate;
constraining the tips of the plurality of elastic core members at a fixed distance from the front surface of the substrate, wherein the distance is fixed by a plurality of spacers distributed across at least a portion of the front surface; and
controllably heating the plurality of elastic core members for any of increasing resistance to any of set and cracking through repeated cycles of deflection of the elastic core members, and plastic deformation of each of the elastic core members.

12. The process of claim 11, wherein the distributed spacers comprise any of shims and spheres.

13. The process of claim 11, wherein the distributed spacers comprises any of metal, ceramic, glass, and a semiconductor.

14. The process of claim 11, wherein the step of constraining the tips of the plurality of elastic core members at a fixed distance from the front surface of the substrate further comprises constraining the substrate a fixed distance over a reference plate.

15. The process of claim 14, wherein the reference plate and the distributed spacers are magnetically attached to each other.

16. A probe card assembly, comprising:
a motherboard substrate having a bottom surface and a top surface, and a plurality of electrical conductors extending from the bottom surface to the top surface;
a probe chip substrate comprising a probe surface and a connector surface, a plurality of probe springs on the probe surface, a plurality of electrical contacts on the connector surface, and a plurality of probe chip electrical connections, wherein each of the probe springs is electrically connected to at least one contact through at least one probe chip electrical connection;
a daughter card comprising a substrate located between the motherboard substrate and the probe chip substrate, the daughter card further comprising at least one electrically conductive connection between each of the plurality of electrical contacts on the probe chip substrate and each of the electrical conductors on the bottom surface of the motherboard substrate;
at least one separable connector located between the motherboard substrate and the daughter card, the at least one separable connector having a range of vertical compliance and comprising at least one electrically conductive connection between each of the plurality of electrical contacts on the probe chip substrate and each of the electrical conductors on the bottom surface of the motherboard substrate; and
a plurality of mechanical connectors between the motherboard substrate and the daughter card, the plurality of mechanical connectors providing an adjustable distance between the mother board and the daughter card.

17. The probe card assembly of claim 16, wherein the plurality of mechanical connectors comprise differentially threaded activators.

18. The probe card assembly of claim 16, wherein the plurality of mechanical connectors are adjustably settable throughout the height range of the separable connectors.

19. The probe card assembly of claim 16, wherein the plurality of mechanical connectors are adjustably settable to provide control over any of separation distance and planarity between the probe chip contactor and the motherboard.

20. The probe card assembly of claim 16, wherein the plurality of mechanical connectors are adjustably settable to provide control over any of separation distance and planarity between the daughter card and the motherboard, and wherein at least one of the plurality of mechanical connectors is further adjustably settable to provide planarity adjustment of the probe chip contactor.

21. The probe card assembly of claim 16, further comprising:
at least one stiffener structure fixedly attached to the daughter card.

22. The probe card assembly of claim 21, further comprising:
a mechanism for providing any of vertical tension and compression to the daughter card through the at least one stiffener structure.

23. A process, comprising the steps of:
providing a probe card assembly comprising
a motherboard substrate having a bottom surface and a top surface, and a plurality of electrical conductors extending from the bottom surface to the top surface,
a probe chip substrate comprising a probe surface and a connector surface, a plurality of probe springs on the probe surface, a plurality of electrical contacts on the connector surface, and a plurality of probe chip electrical connections, wherein each of the probe springs is electrically connected to at least one contact through at least one probe chip electrical connection,
a daughter card comprising a substrate located between the motherboard substrate and the probe chip substrate, the daughter card further comprising at least one electrically conductive connection between each of the plurality of electrical contacts on the probe chip substrate and each of the electrical conductors on the bottom surface of the motherboard substrate,
at least one separable connector located between the motherboard substrate and the daughter card, the at least one separable connector having a range of vertical compliance and comprising at least one electrically conductive connection between each of the plurality of electrical contacts on the probe chip substrate and each of the electrical conductors on the bottom surface of the motherboard substrate, and
a plurality of mechanical connectors between the motherboard substrate and the daughter card, the plurality of mechanical connectors providing an adjustable distance between the mother board and the daughter card;
adjustably setting each of the plurality of mechanical connectors for any of separation distance and planarity between the daughter board and the motherboard; and;
subsequently setting at least one of the plurality of mechanical connectors to provide subsequent planarity adjustment by deflecting the probe chip contactor.

24. A probe card assembly, comprising:
a motherboard substrate having a bottom surface and a top surface, and a plurality of electrical conductors extending from the bottom surface to the top surface;
a probe chip substrate comprising a probe surface and a connector surface, a plurality of probe springs on the probe surface, a plurality of electrical contacts on the connector surface, and a plurality of probe chip electrical connections, wherein each of the probe springs is electrically connected to at least one contact through at least one probe chip electrical connection;
a central structure comprising a substrate located between the motherboard substrate and the probe chip substrate, the central structure comprising electrical connections between each of the plurality of electrical contacts on the probe chip substrate and each of the electrical conductors on the bottom surface of the motherboard substrate;
a stiffener having a front surface and a back surface, the front surface in contact with at least a portion of the top surface of the motherboard substrate, wherein the stiffener has a thermal expansion coefficient that is less than the thermal expansion coefficient of the motherboard substrate; and
a plurality of mechanical connectors between the stiffener and the central structure.

25. The probe card assembly of claim 24, wherein the plurality of mechanical connectors provide an adjustable distance between the mother board and the central structure.

26. The probe card assembly of claim 24, wherein the stiffener is comprised of a material chosen for any of reducing soak time and increasing thermal stability.

27. The probe card assembly of claim 24, wherein the stiffener comprises any of Nobinite, mehanite, and invar.

28. The probe card assembly of claim 24, wherein the stiffener has a thermal coefficient of expansion less than 6×10⁻⁶/° C. @20-50° C.

29. The probe card assembly of claim 24, wherein the designated number of attachment points between the motherboard and the central structure is minimized.

30. The probe card assembly of claim 24, wherein the central structure comprises a Z-block and an associated Z-block flange, and wherein the plurality of mechanical connectors and connected to the Z-block flange.

31. A probe card assembly comprising:
a motherboard substrate having a bottom surface and a top surface, and defining a central region and an outer region extending from the central region, and a plurality of electrical conductors extending from the bottom surface to the top surface;
an interposer substrate comprising an upper surface and a lower surface opposite the upper surface, a plurality of spring contacts on the lower surface, a plurality of electrical contacts on the upper surface, and a plurality of electrically conductive connections between the plurality of spring contacts and the plurality of electrical contacts;
a probe chip substrate comprising a probe surface and a connector surface, a plurality of probe springs on the probe surface, a plurality of electrical contacts on the connector surface, and a plurality of probe chip electrical connections, wherein each of the probe springs is electrically connected to at least one contact through at least one probe chip electrical connection;
a central structure comprising a Z-block substrate located between the interposer substrate and the probe chip substrate, the central structure comprising electrical connections between each of the plurality of electrical contacts on the probe chip substrate and each of the spring contacts on the bottom surface of the interposer substrate;
a stiffener having a front surface and a back surface and fixedly attachable to a prober head plate, the front surface in contact with at least a portion of the top surface of the motherboard substrate; and
a plurality of mechanical connections between the stiffener and the central structure surrounding the interposer substrate, the mechanical connections configured to decouple any of radial and vertical thermal expansion and contraction of the motherboard, to thermally stabilize the orientation of the probe chip substrate relative to the prober head plate.

32. The probe card assembly of claim 31, wherein any of the expansion and contraction of the outer region motherboard substrate reduces a tendency for thermal instability of the probe card assembly.

33. A probe card assembly, comprising:
a motherboard substrate having a bottom surface and a top surface, and a plurality of electrical conductors extending from the bottom surface to the top surface;
a probe chip substrate comprising a probe surface and a connector surface, a plurality of probe springs on the probe surface, a plurality of electrical contacts on the connector surface, and a plurality of probe chip electrical connections, wherein each of the probe springs is electrically connected to at least one contact through at least one probe chip electrical connection;
a central structure comprising a substrate located between the motherboard substrate and the probe chip substrate, the central structure comprising electrical connections between each of the plurality of electrical contacts on the probe chip substrate and each of the electrical conductors on the bottom surface of the motherboard substrate;
a stiffener having a front surface and a back surface, the front surface in contact with at least a portion of the top surface of the motherboard substrate, wherein the stiffener extends outward to be connectable and referenceable to a prober head plate; and
a plurality of mechanical connectors between the stiffener and the central structure.

34. A process, comprising the steps of:
providing a workpiece having a first side and a second side, electrical contacts extending from the first side to the second side, and electrically conductive spring probes on the first side that are electrically connected to the contacts;
immersing the lifted spring probes in a plating solution, while providing a liquid tight seal around the first side of the substrate;
connecting an electrical source to the contacts from the second side of the workpiece; and
plating the immersed spring probes with at least one plating layer.

35. The process of claim 34, wherein the workpiece comprises any of an interposer and a probe chip contactor.

36. The process of claim 34, wherein the workpiece further comprises an electrically conductive layer over the second side and electrically connecting the contacts.

37. The process of claim 36, further comprising the step of:
stripping the electrically conductive layer from the second side of the workpiece.

38. The process of claim 34, wherein the at least one plating layer comprises a material chosen for any of increasing spring force of the spring probes, resisting wear of the spring probes, and decreasing resistance of the spring probes.

39. The process of claim 34, wherein the at least one plating layer comprises any of nickel and gold.

40. A process, comprising the steps of:
providing an interposer with lifted springs on both sides;
sputtering an electrically conductive layer, such as copper over the first side;
plating the lifted springs on the second side with at least one outer layer;
stripping the electrically conductive layer from the first side;
sputtering an electrically conductive layer over the second side;
plating the lifted springs on the first side with at least one outer layer; and
stripping the electrically conductive layer from the second side.

41. The process of claim 40, further comprising the step of:
heat treating the plated interposer.

42. The process of claim 40, further comprising the step of:
performing any of metrology and inspection on the plated interposer.

43. The process of claim 40, wherein the at least one outer plating layer comprises a material chosen for any of increasing spring force of the spring probes, resisting wear of the spring probes, and decreasing resistance of the spring probes.

44. The process of claim 40, wherein the at least one outer plating layer comprises any of nickel and gold.
